(19) United States
(12) Patent Application Publication
(10) Pub. No.: US 2002/0185226 A1
(43) Pub. Date: Dec. 12, 2002

(54) Plasma processing apparatus

(76) Inventors: Leslie Michael Lea, Didcot (GB); Janet Hopkins, Crickhowell (GB); Jyoti Kiron Bhardwaj, Cupertino, CA (US); Huma Ashraf, Newport (GB)

Correspondence Address: VOLENTINE FRANCOS, PLLC, SUITE 150, 12200 SUNRISE VALLEY DRIVE, RESTON, VA, 20191, US

(21) Appl. No.: 10/043,265

(22) Filed: Jan. 14, 2002

Related U.S. Application Data
(63) Continuation-in-part of application No. 09/601,958, filed on Aug. 10, 2000.

(30) Foreign Application Priority Data
Jan. 13, 2001 (GB) 0100958.8

(51) Int. Cl. C23F 1/00; C23C 16/00

(52) U.S. Cl. 156/345.35; 118/723 IR

(57) ABSTRACT

A solenoidal magnetic field generated by a coil around the upper chamber A acts as a magnetic plasma attenuator. By judicious adjustment of the magnetic field strength, a dense plasma region forms inside the tube and adjacent to an antenna and is at least partially trapped by the field lines. These field lines intersect the wall of the upper chamber near or on the lid, and either on the upper chamber wall near its base, or on the lid or upper walls of the lower chamber. Significant numbers of radicals can be created in the upper chamber, which then diffuse into the lower chamber. The associated ion flux is reduced, however, because of losses where the field lines intersect the walls, thereby ensuring that the ratio of ion numbers to radical numbers reaching the wafer is reduced.

### CROSS-REFERENCE TO RELATED APPLICATIONS

This is a Continuation-In-Part of U.S. application Ser. No. 09/601,958, filed Aug. 10, 2000, the entirety of which is incorporated herein by reference.

In addition, this is a counterpart of, and claims priority to, British Patent Application 0100958.8, filed Jan. 13, 2001, the entirety of which is incorporated herein by reference.

### BACKGROUND OF THE INVENTION

1. Field of the Invention

This invention relates to a plasma processing apparatus, in particular, although not exclusively, one for reducing and/or homogenising the ion flux of a plasma without affecting the radical number density of the plasma. The invention also relates to means for reducing and/or homogenising the ion flux and means for guiding neutral radicals.

When etching thin films or bulk material on a silicon wafer or work pieces of other material, it is important to be able to achieve simultaneously a high etch rate, an accurate trench profile, and good uniformity of the etch between different areas of the wafer.

A particular method to achieve highly anisotropic etches for high aspect ratio trenches is to use a switched process in which an etch step is alternated with a deposition step. Such a method is disclosed in WO-A-94/14187, EP-A-0822582 and EP-A-0822584.

In the case of deep trench silicon etching, a passivating layer may be deposited on all surfaces of the trench, during the deposition step. During the initial part of the etch step, the passivating layer will be removed preferentially from the bottom of the trench by ion bombardment. This then allows the silicon to be removed by an essentially chemical process, from the bottom of the trench, during the remainder of the etch step. Alternating deposition and etch steps, allows a high aspect ratio trench to be etched, contrasting with the use of the etch step alone which would result in a predominantly isotropic etch.

There are a number of factors which will influence each step of the deep etch process. In particular, during the etch step, the density of radicals will affect the rate of etch of exposed silicon, and the density, energy and direction of positive ions will affect where and how fast the passivating layer is removed.

For deep trench etching it is desirable to utilise a plasma processing apparatus which produces large numbers of radicals to achieve a high silicon etch rate. Indeed, conditions ideal for the etching step may not be ideal for the passivation step. At the same time, sufficient numbers of very directional, relatively low energy ions should be produced to remove the passivating layer from the bottom of the trench without at the same time removing a significant thickness of the photoresist mask. Clearly, once the mask has been etched away it is not possible to continue with the same degree of pattern transfer from the mask.

A plasma processing apparatus will produce both ions and radicals and the number of each will, in general, increase as the power input into the apparatus is increased. The relative numbers of radicals and ions may change with power input conditions, but will not necessarily be the ideal balance required for the deep trench etch.

Plasma may be produced in a first chamber, with the ions and radicals created being allowed to diffuse into a second chamber where etching of, or deposition on, a silicon wafer or other workpiece may take place. This is the concept of a de-coupled plasma source and process chamber. It is frequently advantageous to produce a dense plasma so that there are large numbers of radicals available to increase the rate of the required chemical process, etch or deposition. However, in general, when a dense plasma is created, in addition to a large number of radicals, large numbers of ions will be produced which may contribute to damage of or other undesirable effects on a silicon wafer or other workpiece.

### SUMMARY OF THE INVENTION

The present invention, at least in some embodiments, discloses techniques and devices to adjust the balance of numbers, to modify spatial distributions and allow “discrete” optimisation of both steps (etch and passivation), to ensure the etching of accurate trench profiles, with good uniformity of etch between different areas of the wafer. Methods of largely “decoupling” the generation of the etch species from that of the passivation species are presented. Indeed, the invention is applicable to all plasma processes where this may be beneficial.

According to a first aspect of the present invention, there is provided a plasma processing apparatus comprising means for striking a plasma in a chamber having a gas inlet and a support for a substrate, wherein the apparatus further comprises attenuation means for reducing and/or homogenising the ion flux from the plasma substantially without affecting the radical number density.

The substrate support, and substrate may be electrically biassed as appropriate to the process.

The attenuation means may extend partially or completely across the chamber.

A plasma processing apparatus may refer to an apparatus in which the process plasma is created and maintained by the inductive coupling of RF power into it, and bias is applied to the substrate (which may be a wafer/workpiece) by a second RF power source. However, this description is for the purpose of explaining the concepts involved, and is not intended to preclude apparatus in which plasma is generated by other means such as microwave, ECR, Helicon, Capacitive, DC, and pulsed power discharges etc, nor to preclude apparatus in which bias is applied to the substrate by DC or RF means whether pulsed or not.

The plasma processing apparatus may be used in a continuous or switched process with an attenuation means that may be changed in strength for each of the deposition and/or etch steps in a cyclic etch/deposition process.

The attenuation means may be any suitable attenuator or filter, and particular preferred examples are described below.

The plasma processing apparatus may further comprise means for providing alternating etch and deposition steps. The etch and deposition gases may be fed via the same or separate distribution systems.

Whilst SF₆ is used as an example of the etch gas, other etch gases may be used, and these are well known to those skilled in the art.

In a preferred embodiment, at least a portion of the chamber is formed of a dielectric material. Particularly, it is preferred that an upper part of the chamber is formed of a dielectric material, where the substrate support is in the lower part of the chamber. Preferably, an antenna is positioned externally adjacent the dielectric portion and this may serve to create a plasma production region in the chamber. The antenna may be used to inductively couple RF power into the plasma which is formed inside the apparatus. The frequency of the RF power is typically 13.56 MHz, but other frequencies may also be used.

The substrate support is preferably energised from a second RF supply. It is well known by those familiar with such systems, that the application of RF power to a substrate which is immersed in a plasma results in the formation of a quasi DC bias on the substrate, such as to accelerate positive ions towards the substrate.

The attenuation means may be positioned above the substrate on the support, and it is particularly preferred that it is positioned between the plasma production region and the substrate. The attenuation means has the purpose of attenuating the flux of ions which reach the substrate, while still allowing a dense plasma to exist in the production region.

The attenuation means has virtually no effect on the neutral radicals which are produced in the plasma production region, or in an upstream chamber, except for any small level of deposition or recombination on the attenuation means.

The attenuation means may comprise a magnetic portion. In particular, the attenuation means may comprise one or more permanent magnets. Alternatively, the attenuation means may comprise means for creating an electromagnetic field, for example in a variable manner. For example, the means may comprise a current carrying conductor. This has the advantage over using permanent magnets in that by adjusting the current passing through the conductor, the magnetic field strength may be adjusted as appropriate for any particular process. In a preferred structure the means for creating an electromagnetic field would comprise an array of electromagnetic coil groups separately orientated to create respective magnetic fields which are angularly offset with respect to one another. Advantageously three sets of coil groups are provided which are designed to create magnetic fields which are offset from one another by 60 degrees or 180 degrees. These can be energised in sequence to create a rotational field. Where the coils have the 60 degree offset, a full 360 degree rotational effect can be achieved by reversing the polarity of the power supply after an initial sequence of energisations of the three groups has taken place.

If desired the attenuation means may comprise both one or more permanent magnets and means for creating an electromagnetic field so that a chosen proportion of the field strength is constant from the permanent magnets, but may be increased or decreased by altering the current creating the electromagnetic field. As the electromagnetic field is only a proportion of the total field, the required current will be reduced when compared with that needed to create a total field, leading to a requirement for a smaller power supply and smaller cross-section conductors. This provides the possibility of, for example, making use of the attenuation during the etch step of a switched process, but reducing or switching off the field entirely during the deposition step. In fact the magnetic attenuation/filter strength can become a process variable, altered between steps of a switched process, or varied during the course of a non-switched process, or varied during the course of a switched process, or both altered between steps of a switched process with more gradual variation superimposed over the course of the process.

The attenuation means preferably produces a high field capable of significantly reducing the ion flux during the etch step. The magnetic field strength is preferably between 50 Gauss and 500 Gauss and is even more preferably between 150 Gauss and 300 Gauss.

In one embodiment, the attenuation means may comprise one or more tubular members carrying permanent magnets or conductors to form an electromagnet. These may be parallel to each other and, for example, may be parallel to the surface of the support, however, neither of these orientations is essential. They may extend over the full width of the chamber to provide a complete filter, or over part of the width to form a partial filter or may be spaced further apart, or utilising weaker magnets to form a partial filter. Additionally, or alternatively, the attenuation means may be substantially parallel to the side walls of the chamber, although this should not preclude the use of attenuation means for which the spacing from the wall of the chamber varies along their length. In one embodiment, the attenuation means extends from the lid of the chamber to a plate member extending from a wall of the chamber, preferably having an appropriately (for example centrally) located aperture therein. As an alternative, the upper end of the attenuation means may terminate on a plate member. Therefore, the attenuation means in such an embodiment may or may not extend all the way between the top and bottom of the dielectric window.

The attenuation means may be temperature controlled, for example cooled. Any suitable cooling medium may be used but specific examples are forced air and water. The cooling medium may be passed through the tubular members to ensure that the magnets are not subjected to high temperatures. A distribution member, for example in the form of a manifold, may be provided to distribute the cooling medium to the attenuation means.

The attenuation means and/or the distribution member may be electrically biased.

In one embodiment, the attenuation means may comprise one or more strong magnets and these are preferably positioned outside the plasma chamber, although alternatively they may be positioned just inside the chamber and are preferably cooled. Again, in such an embodiment, the strong magnets can be in the form of permanent magnets, electromagnets, or a combination of both.

The attenuation means may comprise a sheet member having a plurality of apertures therein, for example in the form of a “grid”. The grid may have varying sizes of apertures at different positions and may have solid sections. In this embodiment, the sheet member is preferably metallic.

The purpose of the sheet member is to attenuate the ion flux reaching the substrate due to ion loss on the sheet member and also, if it is of metallic construction, to define an equi-potential plane for the plasma, so that ions which are accelerated towards the wafer pass through a well defined potential gradient between two parallel surfaces. The sheet member may be biased electrically with respect to the metallic components of the chamber—a negative bias on the sheet member will aid in the collection of ions.

If the overall “transparency” of the sheet member is low, there is the hazard that sufficient deposition may occur on it, thereby resulting in a reduction of deposition rate on the substrate during the deposition step. This factor may be reduced by heating the sheet member. In one embodiment, the sheet member may be positioned substantially parallel to the surface of the support, preferably at or near the bottom region of the dielectric window. Alternatively, the sheet member may be cylindrical. In such an embodiment, the apparatus may further comprise means for providing a gas (etch or deposition) to the chamber on either or both sides of the cylinder; this will depend on whether an etch step or a deposition step is in progress.

The sheet member may be located part way down the dielectric portion and may be supported in any suitable manner. For example, it may be supported from the lid of the chamber by means of a first supporting member and/or from below the dielectric portion by means of a second sheet supporting member. The sheet supporting members may be formed of any suitable material, but one example is a slotted conducting material. Alternatively, two dielectric portions of the chamber may be provided (a first and a second dielectric portion) having the attenuation means positioned therebetween. This allows a more practicable means of electrically biasing the sheet member and the general concept is also transferable to other geometries of the process apparatus.

Two or more antennae may be positioned externally adjacent the dielectric portion or portions and at least one antenna preferably lies above the level of the attenuation means, and at least one antenna lies below the level of the attenuation means. In such an embodiment, the chamber may be provided with an inlet to provide a gas or gases above the level of the attenuation means and a further inlet for providing a gas or gases below the level of the attenuation means. In particular the further antenna (or other means for striking a plasma) below the attenuation means may be provided for the deposition step of an etch/deposition process. Thus, where a further antenna is below the attenuation means, gas may be provided below the level of the attenuation means.

According to a further aspect of the present invention, there is provided an attenuation means for use in a plasma processing apparatus having means for striking a plasma in a chamber, wherein the attenuation means is capable of reducing and/or homogenising the ion flux from the plasma substantially without affecting the radical number density.

The attenuation means may have the preferred or optional features mentioned above.

To etch a substrate with a switched process, as described previously, the attenuation means may be used to reduce the ion flux which reaches the substrate. In one embodiment, an additional means may be used to improve the uniformity of the etch across the substrate by modifying the flux of radicals reaching different areas of the substrate. Thus, the apparatus may further comprise means for guiding neutral radicals. This guiding means will normally act in conjunction with the ion attenuator, but may be used separately if appropriate.

When for example, fluorine radicals are used to etch silicon, the etch rate at a particular position is affected by the amount of surrounding silicon. This is because the silicon etch depletes the available fluorine radical flux. Therefore the etch rate is higher towards the edges of the exposed silicon, where there is less silicon on one or more sides, than at the centre of the substrate. By appropriate design, the guiding means can reduce the fluorine radical flux to the edge of the substrate while maintaining a high flow to the centre, thus reducing or eliminating the effect described above.

The guiding means may comprise a disc or other appropriate shape, which may have one or more apertures in it. In a preferred embodiment it is positioned above the substrate and below the attenuation means. The apertures are preferably shaped in relation to a pattern exposed on a substrate. A part of the guiding means is preferably positioned adjacent the substrate, preferably close thereto, for example at a distance less than 5 cm, typically less than 2 cm.

The guiding means is preferably formed of a conducting material and isolated from the ground, or of a dielectric material. The attenuation and guiding means may be discrete components separately mounted within the process chamber, or may be combined into a single module. The spacing between the attenuation and guiding components may be adjusted as appropriate, but at least part of the guiding means will usually be parallel to, and close to, the surface of the substrate, with the attenuation means nearer to the plasma production region. Furthermore, the precise shape of the guiding means may be adjusted to encourage a pressure or flow gradient across the substrate, in order to further optimise the process rate homogeneity across the substrate surface.

Any aperture(s) in the guiding means, and/or the external shape of the guiding means, may be appropriate to the shape of the substrate or to the shape of the pattern on the substrate. For example, a square aperture may be used in the guiding means if a square pattern is to be etched on a standard round wafer or for a square wafer.

Thus, according to a further aspect of the present invention, there is provided a guiding means for use in a plasma processing apparatus having means for striking a plasma in a chamber, wherein the guiding means is capable of guiding neutral radicals of an etch gas introduced into the chamber.

According to a further aspect of the present invention, there is provided a plasma processing apparatus comprising means for striking a plasma in a chamber having a gas inlet and a support for a substrate, wherein the apparatus further comprises a guiding means.

According to a further aspect of the present invention, there is provided a method of etching a feature in a substrate in a chamber, the method comprising striking a plasma in the chamber and reducing and/or homogenising the ion flux from the plasma substantially without affecting the radical number density. The method may comprise the step of alternately etching the substrate and depositing a passivation layer on the substrate.

According to a further aspect of the present invention, there is provided a method of etching a feature in a substrate in a chamber, the method comprising alternately etching the substrate and depositing a passivation layer on the substrate, wherein neutral radicals during the etch step are guided by a guiding means to improve the uniformity of etching across the substrate.

For high etch rates, the number of radicals needs to be increased, and this may be achieved in a number of ways:

(a) By increasing the source power, the precursor gas dissociation fraction is increased. For example, SF₆→SFₓ+yF. However, the efficiency is limited in terms of the number of fluorine radicals released from each SF₆ molecule, i.e. two fluorine radicals are readily liberated. However, the stability of the dissociates and recombination reactions limit release of more than two fluorine radicals from each SF₆ molecule. Even so, the etch rate can be significantly enhanced by the method of increasing the source power to effectively dissociate a greater number of SF₆ molecules. Once saturation occurs with respect to the fluorine radical yield, further rate enhancement can only be achieved by increasing the gas flow rate in proportion to the RF power;

(b) As pressure is increased, the radical number density increases as the number of collisions increases. But as the pressure is increased, the plasma density in low pressure high density systems can be reduced due to the “scattering” collisions which reduce the degree of confinement. Also pressure increase reduces etched profile anisotropy, as collisions impair the degree of directionality of ions. The result is profile deterioration through “bowing” etc, which becomes worse as the aspect ratio increases. Therefore, this method is also limited in application.

A means for overcoming the limitations and further enhancing the etch rate is by using a high power pulsed source. By using very high power pulses (ref. GB-A-2105729; G. Scarsbrook, I. P. Llewellyn and R. A. Heinecke. J. Vac Sci. Technol. A&(3), May/June 1989; and I. P. Llewellyn, G. Scarsbrook and R. A. Heinecke. SPIE Vol. 1148 Nonlinear Optical Properties of Materials (1989)) complete gas dissociation can occur, resulting in total fragmentation of the precursor.

Thus, according to a further aspect of the present invention, there is provided a method of etching a feature in a substrate, the method comprising applying pulsed high power to an etch source gas, and alternately etching the substrate and depositing a passivation layer on the substrate in a chamber.

The high power is preferably applied for between 100 microseconds and several milliseconds during each pulsed cycle. In a preferred embodiment, the power density of the pulsed high power is between 10 and 300 W/cm³.

The method may further comprise the step of reducing and/or homogenising the ion flux from the plasma substantially without affecting the radical number density and, for example, any of the above-mentioned methods can be used. The method may additionally, or alternatively, comprise the step of guiding neutral radicals.

According to a further aspect of the present invention, there is provided a plasma processing apparatus for performing the above method, the apparatus comprising a first chamber having an inlet for an etch source gas and a second chamber having a support for a substrate, wherein the first and second chambers are connected via an aperture, and wherein the apparatus further comprises a means for providing pulsed high power to the first chamber.

The pulsed high power discussed below is RF, but any power may be used, for example microwave or DC.

In one embodiment, the first chamber may comprise a dielectric window and the means for introducing the RF pulsed high power is an antenna which is preferably positioned externally adjacent the dielectric window.

The second chamber may be actually separated by a separating member from the first chamber and indeed more than one first chamber providing a pulsed source may be used.

The second chamber may have a separate gas inlet.

Preferably, the plasma processing apparatus further comprises attenuation means which may be in the region of the aperture. This attenuation means may be the same as the forms mentioned above, but is preferably in the form of magnets placed on either side of the aperture to form a magnetic filter. This improves the confinement of the pulsed plasma within the source. Alternatively, magnets may be located in tubes across the aperture in, for example, a similar configuration to that described above.

In one embodiment, a restricted conductance aperture connects the first and second chambers which allows a higher source pressure to be practically utilised.

According to a further aspect of the present invention, there is provided a method of etching a feature in a substrate, the method comprising applying a high density radical source to an etch source gas, and alternately etching the substrate and depositing a passivation layer on the substrate in a chamber.

The etch and/or deposition steps preferably take place by means of a plasma.

It is another object of this invention to provide means whereby the ratio of radicals to ions can be controlled such that a reduction in the proportion of ions reaching the workpiece may be reduced.

According to still another aspect of the invention there is provided a plasma processing apparatus comprising a first chamber provided with a plasma inducing device designed to produce a plasma in said first chamber, and a second chamber into which plasma so produced can diffuse to act upon a workpiece being processed, and a magnetic field production device positioned relative to at least the first of said two chambers and constructed to cause attenuation of the ions which diffuse into the second chamber and approach the workpiece, by directing a proportion of the ions to a loss surface of either chamber.

The control measures incorporated into the system by the magnetic field device, adjust the relative numbers of ions to radicals, which diffuse into the second chamber and reach the wafer. Thus, the use of suitably orientated magnetic fields will influence ion diffusion while not affecting the diffusion of neutral radicals.

Preferably the magnetic field production device would comprise permanent magnets or electromagnets installed around the side wall of the first chamber. The magnetic field production device around the first chamber could be a solenoid whose output can be varied.

The apparatus could incorporate an additional plasma inducing device at the upper region of the second chamber. In that case permanent magnets, electromagnets or a solenoid may be installed also around said additional plasma inducing device at the upper region of the second chamber, as a further magnetic field production device

Another possibility is that the magnetic field production device comprises a magnetic structure formed at the junction of the two chambers to create a dipole magnetic field there.

The apparatus could incorporate a ring gas feed within the second chamber, below the junction point of the two chambers, in addition to a gas feed inlet to the top of the first chamber.

A solenoid device whose output can be varied may be provided for the second chamber at a position to create a magnetic field inside the second chamber at the level of the workpiece to steer ions towards the workpiece.

The first chamber could be of annular form with the magnetic field production device comprising separate permanent magnets, electromagnets or solenoids located both within and around said annulus.

The first chamber might be formed of two or more differing-diameter cylindrical dielectric sections, one above the other, each such section being provided with its own plasma inducing device.

The second chamber can be provided with a magnetic bucket arrangement created by an array of magnets around the chamber wall.

The first chamber geometry could be formed as a cylinder, a stepped cylinder, a cone, a truncated cone, or a hemisphere, or a combination of these geometries.

According to a further aspect of the invention there is provided a plasma processing apparatus comprising a first chamber provided with a plasma inducing device designed to produce a plasma in said first chamber, and a second chamber into which plasma so produced can diffuse to act upon a workpiece being processed, wherein the first chamber is formed of two or more differing-diameter cylindrical dielectric sections, one above the other, each such section being provided with its own plasma inducing device.

The portions joining the individual sections of said first chamber are ideally formed of metallic or dielectric material and may be positioned perpendicular to or angled to said sections.

The multi-section first chamber can have a magnetic field production device associated with more than one of said sections, each constructed to cause attenuation of the flux of the ions which diffuse into the second chamber and approach the workpiece.

Further annular forms of a first chamber with pairs of attenuation magnetic field production devices positioned concentrically of one another, could be provided to enable processing to be undertaken over a wide area.

Ideally said first chamber will incorporate a dielectric plasma tube formed from aluminium nitride or silicon carbide or other dielectric material having a thermal conductivity sufficiently greater than aluminium oxide to allow high power operation without failure-inducing high thermal gradients arising in the dielectric material.

In order to increase the area of processing activity, a plurality of said first chambers of the form of this invention could be provided across the top of the second chamber.

The invention further extends to a plasma processing apparatus comprising a first chamber provided with a plasma inducing device designed to produce a plasma in said first chamber, and a second chamber into which plasma so produced can diffuse to act upon a workpiece being processed, wherein said first chamber incorporates a dielectric plasma tube formed from aluminium nitride or silicon carbide or other dielectric material having a thermal conductivity sufficiently greater than aluminium oxide to allow high power operation without failure-inducing high thermal gradients arising in the dielectric material.

The control measures may be required to have a functional dependence on time or another parameter, which may be linked to a particular aspect of the etch or deposition process. For example the number of ions reaching a surface being etched may be required to decrease once a surface layer has been removed, while the number of radicals reaching the surface may be required to remain constant. The level of the control measures can be re-adjusted after a given time in which the surface layer has been removed, in order to achieve the new desired ratio of radicals to ions. The control measures may also incorporate a spatial dependence, so that the relative number of ions to radicals can be varied as a function of position on the wafer.

For the etching of deep trenches in silicon or other suitable materials, a switched process may be used (Robert Bosch GmbH US5501893 or Surface Technology Systems Ltd US6051503). In such a process, alternating steps of material deposition and etch occur, with the resultant anisotropic etching of features into the wafer. In greater detail, a polymer is deposited on both the sides and bottom of a trench or other feature during the deposition step. During the following etch step, the polymer is preferentially removed from the bottom of the trench by directed ion bombardment, then allowing a chemical etch of the exposed silicon. Although the chemical etch is essentially isotropic, the overall etch process is anisotropic, because the polymer removal is only from the bottom of the trench, and the silicon etch depth is small for each etch step. A suitable patterned mask of, for example, photoresist is applied to the wafer before the etch process is started in order to define the surface geometry of the features to be etched. It is an important aspect of the overall process, particularly for deep trench etching, that the ion bombardment utilised to remove the polymer from the bottom of the trench, does not erode the mask before the required depth of etch has been achieved, otherwise the definition of the features will be lost.

A number of different arrangements of permanent and electromagnets have been described in our International Patent Application PCT/GB99104168, to allow control of the relative numbers of ions to radicals which are permitted to reach the wafer. In regard to a switched etch process, the field produced by any electromagnet may be adjusted to one level for the etch step and to a different level for the deposition step. In some circumstances it may be advantageous to vary the field strength during either or both of the etch and deposition steps. For example during the etch step, the magnetic field strength may be kept low during the early part, in order to allow a high flux of ions to reach the wafer and remove the polymer which has been deposited on the bottom of a trench. When the polymer has been removed, the field strength can be increased to reduce the ion flux to the wafer and so reduce the mask etch rate. In addition to this, the field may be adjusted from one etch step to the next etch step, and/or from one deposition step to the next deposition step, in order gradually to adjust the relative numbers of ions to radicals as the trench etch proceeds.

This Application describes in detail, features of a plasma processing apparatus which enable a high etch rate to be achieved with good uniformity in the etch rate across the wafer and precise control of the shape of etched features. In this Application, the description is particularly directed towards etching carried out by means of a switched process as described above. This is not intended to preclude the application of aspects of the system to either a continuous etch process or a continuous deposition process (the term “continuous” in this context referring to the feature that the process is “not switched between etch and deposition steps”, rather than any implication that the process rate, or other aspect, remains constant in time).

The plasma processing apparatus includes two or more chambers. In the second chamber, usually the larger, a silicon wafer or workpiece is mounted on a suitable support. This support may incorporate features to allow cooling or heating of the wafer during, before or after processing. The support may also allow an RF or DC voltage, continuous or pulsed, to be applied to the wafer with respect to the chamber, to enable ions to be accelerated to the wafer. Features may be incorporated in the support and in the chamber wall to allow remote loading or un-loading of the wafer. Ports will usually be incorporated in the walls of this chamber for pressure gauges and other diagnostics, with a relatively large port or ports through which gas exits to the vacuum pumping system used to maintain the desired operating pressure in the chamber.

The first chamber or chambers will typically be of smaller volume than the second chamber in which the wafer is mounted. Plasma is created and sustained in this first chamber and ions and radicals diffuse into the second chamber. Control means, such as a magnetic attenuator, may be used to define the flow of ions and radicals into the second chamber. Reference to one chamber does not preclude the use of multiple chambers in which plasma is formed, with multiple control means to control the flow of ions and radicals into the second chamber in which the wafer is mounted. When plasma is formed in multiple first chambers there is no restriction implied on whether all chambers are operating at the same time, whether feed gases are the same, or whether the level of power input to each plasma is the same.

From a still further aspect of the invention there is provided a method of controlling the transmission of a plasma to a workpiece, wherein plasma is created in a first chamber provided by a plasma inducing device, and is allowed to diffuse into a second chamber to act upon a workpiece being processed, and an attenuation magnetic field production device positioned relative to at least the first of said two chambers is operated in a manner to cause attenuation of the ions which diffuse into the second chamber and approach the workpiece, by directing a proportion of the ions to a loss surface of either chamber.

### BRIEF DESCRIPTION OF THE DRAWINGS

The invention may be performed in various ways and various specific embodiments thereof will now be described, by way of example, with reference to the accompanying drawings all of which illustrate embodiments of the invention, and in which:

FIG. 1 is a cross-section of a plasma processing apparatus according to the present invention;

FIG. 2 is a cut-away plan view showing the magnet array of FIG. 1;

FIG. 3 shows an alternative apparatus of the present invention in cross-section;

FIG. 4 shows a plan-section of the embodiment in FIG. 3;

FIG. 5 shows a cross-section of an alternative apparatus;

FIG. 6 shows a cross-section of a further alternative apparatus;

FIG. 7 shows a cross-section of a further embodiment of the apparatus;

FIG. 8 shows a cross-section of a further alternative embodiment;

FIG. 9 shows a cross-section of a further alternative embodiment illustrating the design of an aperture into a plasma chamber;

FIG. 10 shows an enlarged cross-section of another embodiment of an aperture into a plasma chamber;

FIG. 11 is a cross-section of a plasma processing apparatus incorporating a guiding means;

FIG. 12A is a cut-away view of a lower part of a chamber showing a guiding means;

FIG. 12B is an enlarged view of part of FIG. 12A;

FIG. 13 is an alternative apparatus incorporating a guiding means;

FIG. 14 shows experimental measurements of positive ion current density, obtained using attenuation means of the form shown in FIGS. 1 and 2;

FIG. 15 shows experimental measurements at various powers;

FIGS. 16A and B show an electromagnetic coil design;

FIG. 17A, 17B and 17C show particular features of a preferred electromagnetic coil attenuator structure;

FIG. 18 is an illustration of a form of de-coupled plasma source and process chamber of this invention;

FIG. 19 is a horizontal cross-section through the chamber of FIG. 1;

FIGS. 20A to 20C illustrate possible alternative geometries for the shape of the first chamber of the system shown in FIG. 18;

FIG. 21 shows a further possible geometry for the first chamber of the system in FIG. 1 and a magnetic field created therein;

FIG. 22 shows the magnetic field created in a modified form of the system in FIG. 18;

FIGS. 23, 25 and 26 illustrate modified versions of the apparatus as shown in FIG. 18; and

FIG. 24 shows analysis results of experimentation using the apparatus of FIG. 23.

### DETAILED DESCRIPTION OF THE PREFERRED EMBODIMENTS

The present invention will now be described more fully with reference to the accompanying drawings, in which a preferred embodiment of the invention is shown. This invention may, however, be embodied in many different forms and should not be construed as being limited to the embodiments set forth herein. Rather, the embodiments are provided so that this disclosure will be thorough and complete, and will fully convey the concept of the invention.

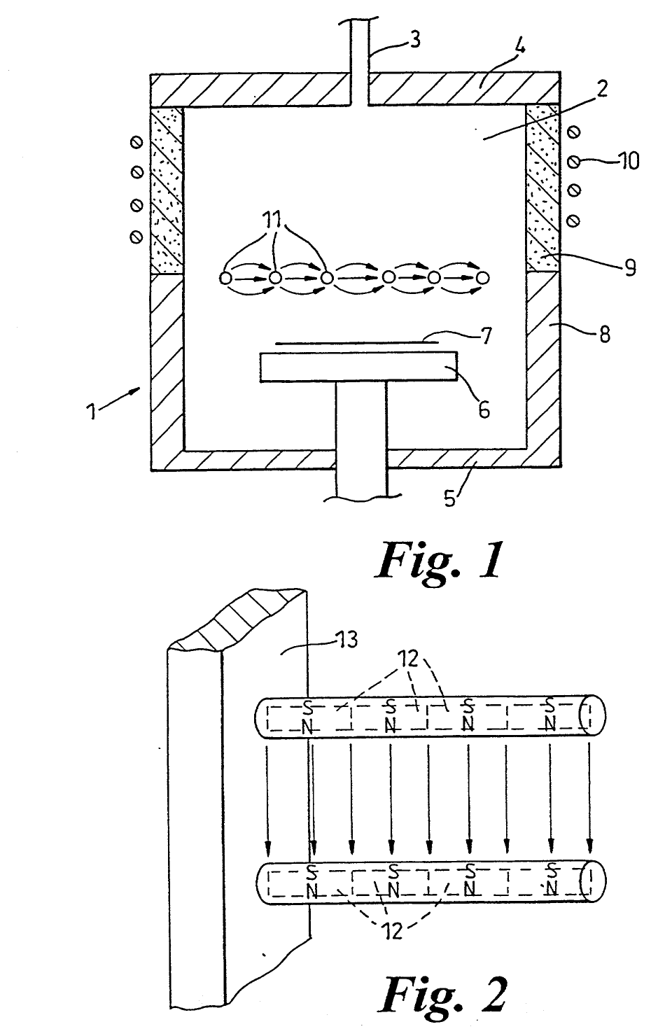

Referring to FIG. 1, there is shown a plasma processing apparatus generally at 1. The apparatus 1 comprises a chamber 2 into which an etch or deposition gas (or both) may be passed through inlet 3 in its lid 4. Extending through the base 5 of the chamber 2 is a platen 6 on which is mounted a wafer 7, for example a semiconductor wafer. The chamber 2 has a side wall 8, the upper region of which is formed as a dielectric window 9. An antenna 10 is located outside of the dielectric window 9 and is used to couple RF power inductively into the plasma which is formed inside the apparatus. The frequency of the RF power is 13.56 MHz, but other frequencies may also be used. In using the embodiment shown, in use etch and deposition gases are fed alternately through the inlet 3, depending on which of the etch or deposition steps is in progress. The platen 6 is energised from a second RF supply.

Within chamber 2, a series of parallel tubes 11 are mounted in a plane parallel to the surface of the platen 6. Each tube contains a small permanent magnet or series of magnets arranged as shown in FIG. 2. Forced air, water or other suitable cooling medium is passed through the tubes to ensure that the magnets are not subjected to high temperatures. The cooling medium is distributed by means of a manifold 13.

In an alternative form, the permanent magnets 12 may be replaced by current carrying conductors in tubes arranged, as mentioned above, in such a way as to create electro-magnetic fields of similar strengths and orientations to those achieved by the permanent magnets. As a further variant, the use of a hybrid of permanent magnets and electromagnets is also envisaged. The principle of operation is that electrons from the plasma created near the antenna 10 move into the region of influence of the magnetic field, are guided by the magnetic field and lost to the wall 8 or manifold 13 due to an E×B drift. The electric field set up in the plasma by the loss of electrons ensures that ions are also attracted to the wall or manifold where they too are lost. The net result is a reduction in plasma density, on transmitting the magnetic field, from the region in which the plasma is produced to the region in which the wafer is placed. The magnetic field has no effect on the radicals, and the magnet carrying tubes have only marginal effect on the radical numbers due to a small degree of recombination on the surface. The magnet carrying tubes and/or manifold may be electrically biased if appropriate.

Use of this magnetic attenuator allows high RF powers to be applied to the plasma source, producing the high numbers of radicals needed for a high etch rate, but limits the number of ions which can reach the wafer so that the physical component is homogeneous and well controlled. Benefits include not only utilisation of high source power plasmas (allowing high etch rates), but also of enhancing the uniformity of the etch.

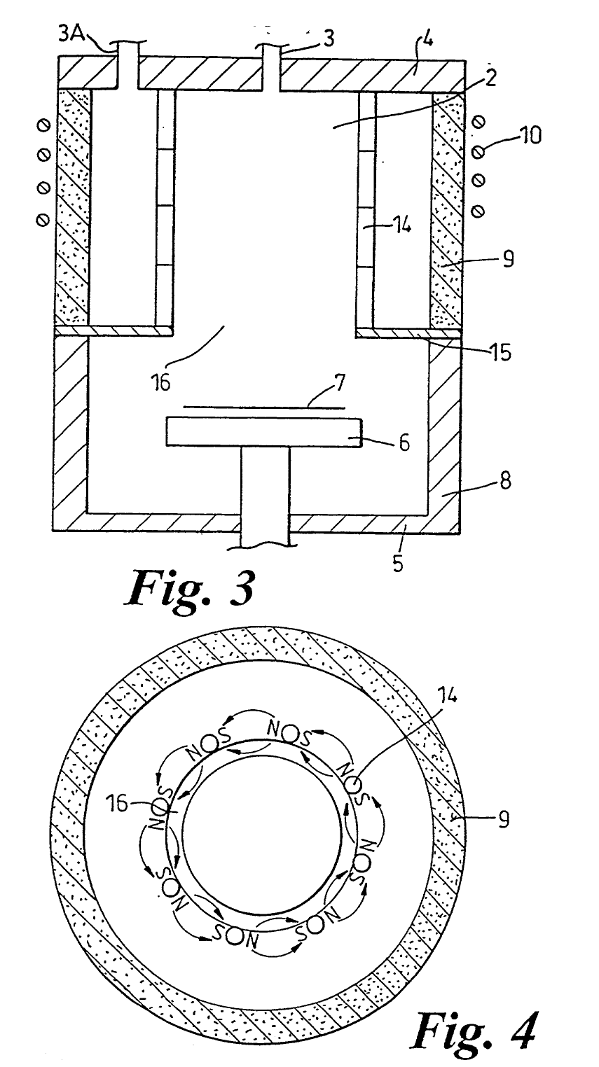

FIGS. 3 and 4 show a variation in the apparatus in which identical reference numerals correspond to essentially identical parts. In the embodiment shown, permanent magnet carrying tubes 14 extend vertically and are placed in a “cage” arrangement to form an internal magnetic “bucket”, with each tube substantially parallel to the dielectric window 9 and side wall 8. The principle of operation is the same as that described with reference to FIGS. 1 and 2 above. In FIG. 3, the tubes 14 are shown as terminating at their upper ends in the lid 4 of the chamber 2 and at their lower ends in a plate 15 having a central aperture 16. However, it should be noted that the upper ends of the tubes 14 need not necessarily terminate in the lid of the chamber, and may alternatively terminate in a similar plate to that used to locate the lower ends. The plate 15 or lid 4 allows the tubes 14 (which are normally conducting) to be electrically biased or grounded. The tubes 14 will provide a degree of electrostatic screening in addition to the magnetic filter structure and therefore will assist in decoupling the plasma generation local to the antenna from ion acceleration to the wafer which is brought about by the RF bias applied to the platen 6.

The magnet carrying tubes 14 may be air or fluid cooled, and if so will require suitable manifolds or interlinking at top and bottom ends.

Similarly to the planar magnetic filter, the permanent magnets may again be replaced by current carrying conductors in a suitable configuration of tubes to form an equivalent electromagnetic field. In addition, a hybrid of permanent and electromagnets may be used to form the required field pattern. Also shown in FIG. 3 is a second inlet 3A and this inlet 3A and inlet 3 may be attached to one or more distribution systems in order to feed the chamber with etch and/or deposition gases.

FIG. 5 shows a further alternative arrangement. In the embodiment shown, outside chamber 2 are positioned strong magnets 17 adjacent to the sidewall 8, just below the level of the dielectric window 9. The strong magnets 17 create a long range magnetic field. This arrangement is simpler and cheaper to construct, but suffers from the disadvantage that the magnetic field will have a significant magnitude throughout a sizable part of the apparatus. This may affect the plasma production region and perhaps more seriously, may result in a significant magnetic field strength at the wafer surface. The magnetic field may be created by permanent magnets or electromagnets, or a combination of both.

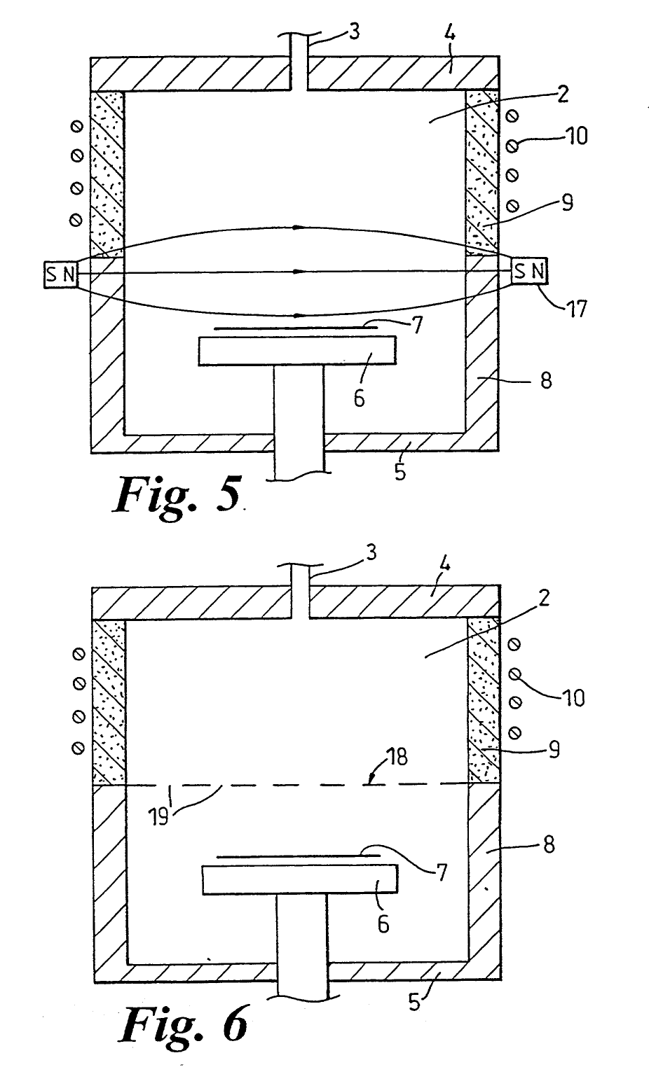

FIG. 6 shows an alternative arrangement in which a horizontally disposed grid 18 is located across the chamber 2, separating the plasma production region, adjacent to the dielectric window 9, from the wafer 7. The grid 18 has apertures 19 of varying sizes at different positions and may have solid sections with no apertures. The effect of the grid 18 is to attenuate the ion flux reaching the wafer due to ion loss on the grid 18, as described above.

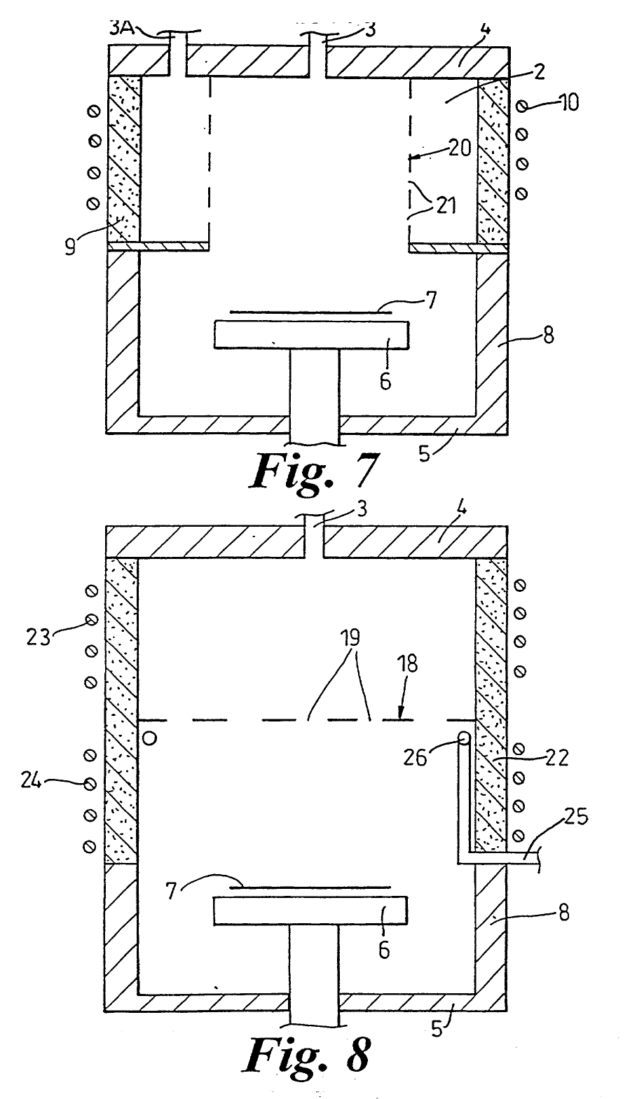

FIG. 7 shows a variation of the design described with reference to FIG. 6. In this embodiment, grid a 20 having apertures 21 is of cylindrical form (for a cylindrical process chamber). Gas may be fed in at either or both of inlet 3 or the second inlet 3A depending on whether a deposition step or an etch step is in progress. Similarly to the system as described with reference to FIG. 3, the grid 20 may or may not extend all the way from the lid 4 to the bottom of the dielectric window 9.

A more complex form of the plasma processing apparatus is shown in FIG. 8. A grid 18 is located part way down a dielectric window 22. The grid 18 may be supported from the lid 4 or from below the dielectric window 22. As proposed above, the grid 18 may have a number of identical apertures in it or may have sections additionally having larger apertures or sections which are blanked off with the aim of producing spatial improvements in the uniformity of the overall etch at various positions on the wafer 7. Two antennae 23, 24 are wound around dielectric window 22, antenna 23 being positioned above the level of grid 18 and an antenna 24 being positioned below it. Gas is fed through inlet 3 to the chamber and a further gas inlet 25 feeds a gas ring 26 or similar gas distribution device located below grid structure 18. As before, the wafer 7 is supported on a platen 6 near the bottom of the chamber.

With the similar plasma processing chambers shown in FIGS. 6 and 7, passivating material may be deposited on the grid structure during the deposition step. This effect may be reduced by ensuring that the grid structure is heated, but there may still be a need for enhanced passivation when the grid structure is present.

For the apparatus shown in FIG. 8, the preferred method of operation is as follows. For the etch step, gas is fed into inlet 3 and antenna 23 is energised. Radicals pass through the grid structure 18 down to the surface of the wafer 7, while the positive ions are attenuated and their spatial distribution modified by the grid structure. If found to be of benefit, antenna 24 may also be energised at a low power level, and some gas used in the etch step may be introduced through gas inlet 25. For the deposition step, the appropriate gas is fed to gas inlet 25, and antenna 24 is energised. It would not normally be necessary to energise antenna 23 or feed gas into inlet 3 during the deposition step of the process.

For the apparatus shown in FIG. 8, the grid structure 18 may be replaced by a magnetic attenuator of any of the forms previously described, with the operating scenario essentially unchanged.

As discussed above, a means for further enhancing the etch rate is to use a high power pulsed source. By using very high power pulses, complete gas dissociation can occur, resulting in total fragmentation of the etch gas precursor. Thus, for example, where SF₆ is the etch gas, complete gas dissociation occurs as follows:

SF₆→S+6F

Typical pulsed RF power levels and pulse duration are of the order of 50 kW and 200 μS respectively, but the pulsed power required is a function of the source size, and requirements may be as high as 200-300 W/cm³ to achieve high dissociation of the gas. The range of conditions that are relevant here include 100 μS to several mS pulse duration and 10 to 300 W/cm³ power density, depending on the degree of dissociation enhancement required. The source may comprise cooled members to enhance sulphur condensation on to the surface.

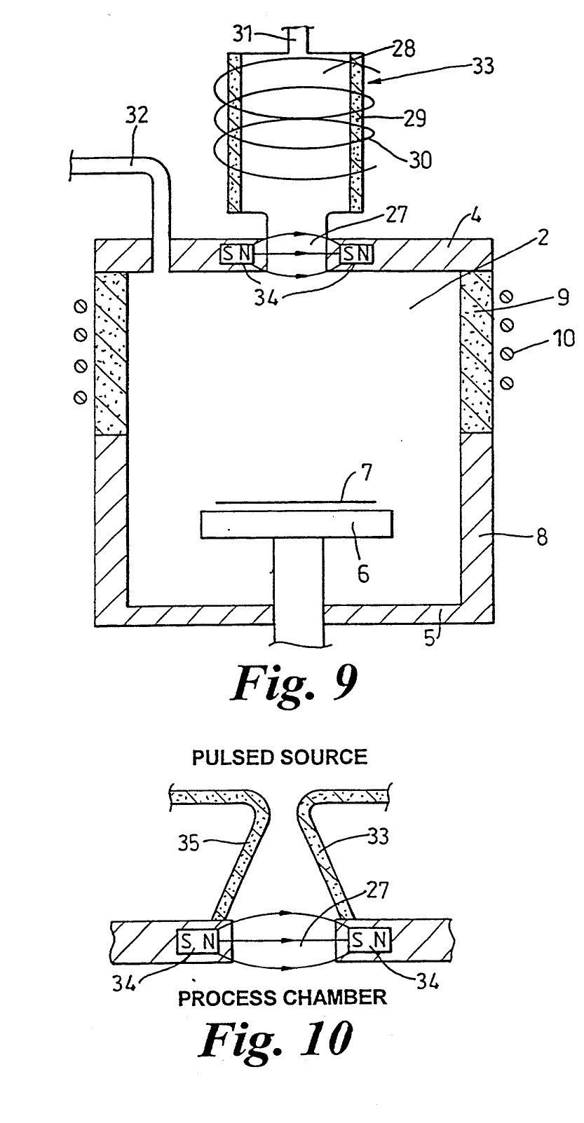

FIG. 9 shows an apparatus for achieving these requirements. In the embodiment shown, an aperture 27 is present in the lid 4 of chamber 2. Extending from the aperture 27 is a subsidiary chamber 28 having dielectric window sidewalls 29 around which is wound antenna 30. The subsidiary chamber 28 has an inlet 31 in its upper surface for providing the etch gas. Also positioned in the lid 4 of chamber 2 is inlet 32 through which is provided the passivation gas or an etch related gas. Antenna 10 around dielectric window 9 forms the passivation or etch plasma as above. The subsidiary chamber 28, dielectric side walls 29, antenna 30 and inlet 31 together form a high power pulsed source generally shown at 33. The aim is to produce copious numbers of radicals within the pulsed source 33 which then diffuse into the main process chamber. In order to improve the confinement of the pulsed plasma within the source, magnets 34 are positioned either side of the aperture 27 to form a magnetic filter. Alternatively, magnets may be located in tubes across the aperture in a similar configuration to that shown in FIGS. 1 and 2, for example, for dividing the main process chamber 2.

FIG. 10 shows an alternative embodiment in the region of the aperture 27. In this embodiment, the lower portion of the subsidiary chamber comprises walls 35 which converge at their upper end opposite the end at aperture 27. Although the Figure shows tapering of the dielectric section, this section may alternatively may be of metallic construction, possibly as an extension of the separating member structure. This provides a low pumping conductance aperture and, in such an embodiment, the pressure in the pulsed high power plasma source may be increased without having a detrimental effect on the pressure in the main process chamber 2.

The aim of the embodiments presented in FIGS. 9 and 10 is to create a high radical density source which can provide a means for carrying out the etching step while the deposition plasma source is separated. The high pulsed power source presented above can be replaced by any high density radical source (whether plasma or non plasma). When this source produces undesirable electrically charged components, the attenuation means described above can effectively be used to restrict their transmission to the wafer. But where the source predominantly generates radicals only, such attenuation means would not be necessary. Here, the scope of the invention reverts to the use of a high radical source comprising the etch step species generation within the etch/deposition cyclic processing regime.

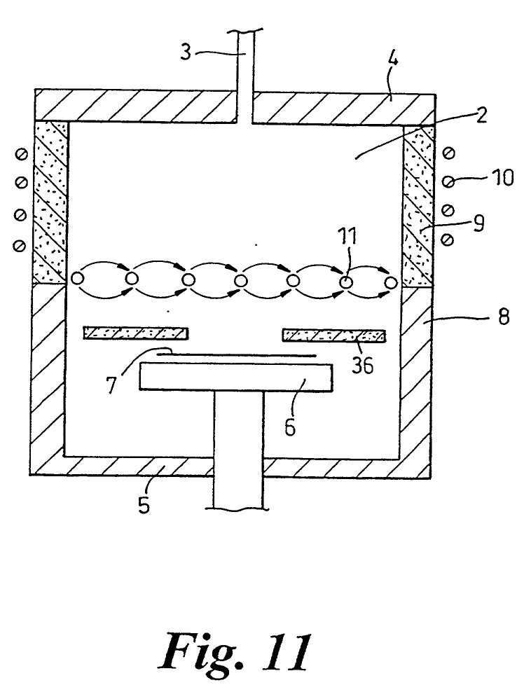

FIG. 11 shows an apparatus similar to that in FIG. 1, except that it incorporates a guiding means in the form of a disc 36. The disc 36 is positioned above wafer 7 and below tubes 11 and may have one or more apertures therein. Radicals may reach the wafer 7, where chemical reactions will take place, by passing through the aperture(s), or around the disc 36, and diffusing over the surface of the wafer 7. Thereby, the function of the disc 36 is to reduce the processing rate (by limiting the flux density) at areas located beneath it. The closer the disc 36 is to the wafer 7, the greater the attenuation of the processing rate. When the disc 36 is very close to the wafer 7 (spaced less than 10 mm), there is a possibility of local electromagnetic field perturbation, particularly if the disc 36 is made of conducting material and grounded. In some applications this may become detrimental. In the preferred embodiment, the disc 36 is either made from a conducting material and isolated from ground, or made from a dielectric material. The isolated conducting material or the or dielectric material will attain the floating potential of the local plasma as a balance occurs between the fluxes of ions and electrons reaching it. Other ions will pass through the aperture(s) in the disc 36, or around it, to reach the substrate.

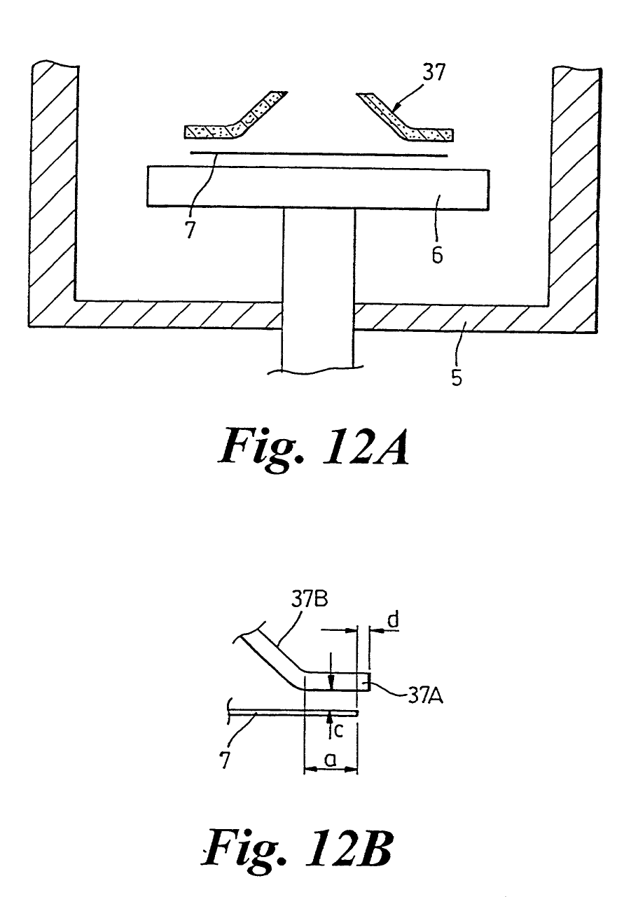

FIG. 12A shows an alternatively shaped guiding means 37, which encourages a pressure or flow gradient across the wafer 7. However, an even more complex geometry (with apertures if necessary) may be used, depending on the substrate and etch pattern shape, reactor design and local pressure and gas flow behaviour. FIG. 12B shows an enlarged view of part of FIG. 12A intended to overcome the excess radical flux to the edge of wafer 7, as described above. The shaped guiding means 37 has a portion 37A parallel to the wafer 7 and an inclined portion 37B. The inclined portion 37B provides increasing flux to the surface of wafer 7—without this, the “edge effect” may occur with respect to the inside edge of the guiding means. In the embodiment shown, dimension d is small, so that the edge of portion 37A is close to the edge of wafer 7. Dimensions a, c and d can be adjusted as necessary to compensate for edge effects.

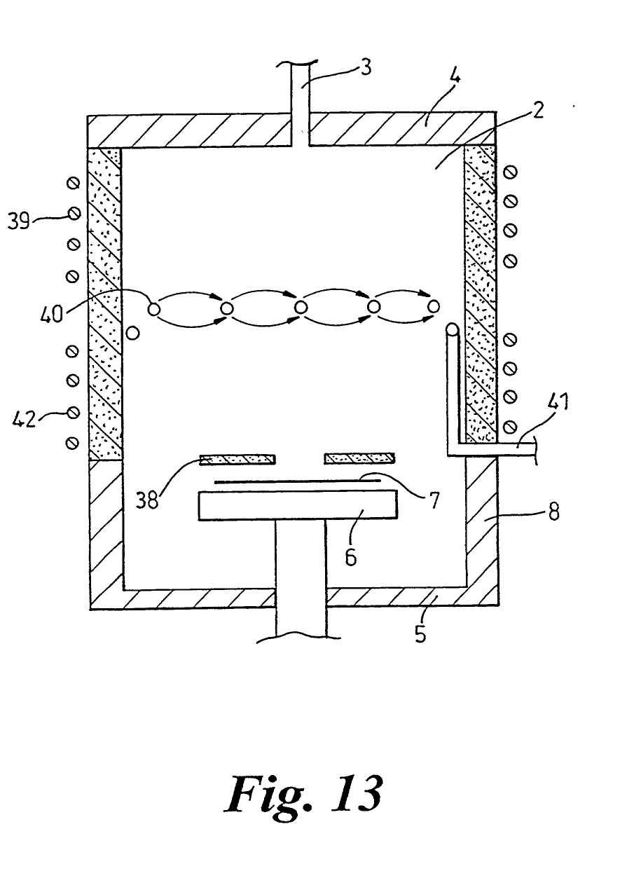

The guiding means may be installed in a process chamber which utilises a de-coupled plasma source, for example as shown in FIG. 13. The guiding structure is shown at 38. Antenna 39 is used to strike and maintain the relatively high power plasma for the etch step, utilising gas from a first gas distribution system through inlet 3. This intense discharge leads to the creation of large numbers of radicals, which diffuse towards the wafer 7 and are guided to the wafer surface by the guide structure 38. The high ion flux from the discharge is reduced by the attenuation structure 40 to an appropriate level for the process.

For the deposition step, gas may be introduced either above or below the attenuation structure 40, through inlet 3, or through inlet 41 linked to a second gas distribution system. Antenna 42 may be used to produce a plasma of suitable density for the deposition process. With this scenario, for the deposition step, antenna 39 would not normally be energised. An alternative arrangement in which antenna 42 is not fitted on the apparatus, would utilise a plasma struck and maintained by antenna 39 utilising the appropriate deposition gas, or alternative gas, fed via gas distribution systems. Deposition gas would be introduced through inlet 41. In either case the deposition material diffuses down to the guide structure 38, where it is guided to the surface of the wafer 7.

The guiding structure may also be used in the apparatus shown in FIG. 9 in which large numbers of radicals are produced in a separate chamber. The purpose of the guiding structure, however, remains the same as described above.

The guiding structure may be heated to reduce the deposition on it.

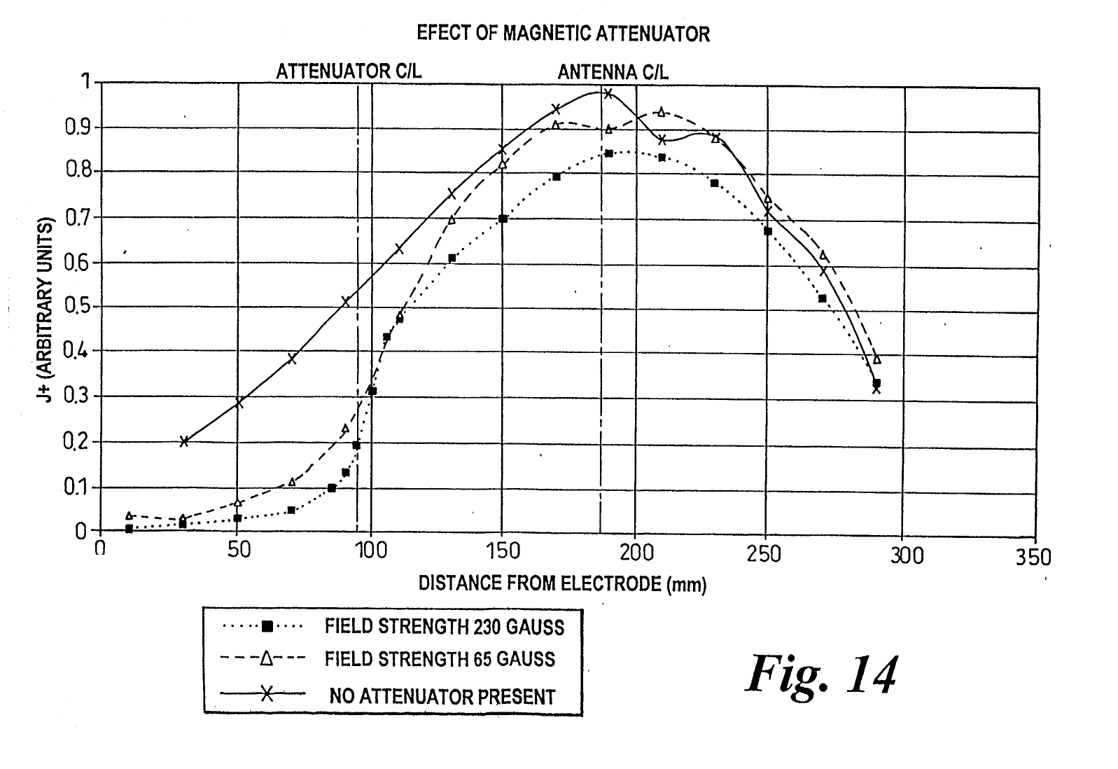

FIG. 14 shows the results from three sets of experimental measurements of positive ion current density plotted against distance above the substrate surface. When two of the sets of measurements were taken, a magnetic attenuator of the form shown in FIGS. 1 and 2 was present.

The conditions were:

(a) No magnetic attenuator in the process chamber.

(b) Magnetic attenuator present, at position shown, with peak field strength of 65 gauss mid-way between the magnet carrying tubes.

(c) Magnetic attenuator present, with peak field strength of 230 gauss mid-way between the magnet carrying tubes.

RF power was applied to an antenna positioned around a dielectric section of the process chamber at the position shown in FIGS. 1 and 2.

The measurements show that the plasma has the greatest density at or near the antenna position, and diffuses both towards the lid of the process chamber and towards the substrate.

The effect of the magnetic attenuator is clearly visible, with the ion density below it, and towards the substrate, significantly reduced.

For the three conditions, simple etch and deposition processes were carried out. The results from these are shown below in table 1.

TABLE 1

| | Field Strength | Deposition Rate | Etch rate |
|---|---|---|---|
| Geometry | (gauss) | (Å/min) | (μm/min) |
| No Attenuator | 0 | 428 | 1.34 |
| Low Field Attenuator | 65 | 110 | 1.03 |
| High Field Attenuator | 230 | Approx. 0 | 0.96 |

The table shows that the magnetic attenuator causes a relatively small reduction in etch rate, as the field strength is increased, but a much greater reduction in the deposition rate.

The etch rate is expected to be primarily determined by relatively long lived neutral radicals formed in the vicinity of the antenna, with a lesser effect due to ions transported to the surface of the substrate. This is consistent with the observed results which show a 30% reduction in the etch rate as the field is increased.

The deposition rate is strongly affected by the presence of the magnetic field, indicating that the charged particle density local to the substrate, is important to the deposition process.

For a switched etch/deposition process, this result indicates the potential advantage of using an electromagnetic attenuator, which could be controlled to provide a strong magnetic field during the etch step and a weak field during the deposition step. Note that the purpose of the strong field during the etch step is to attenuate the ion flux reaching the substrate, which removes the passivating layer, while allowing the plasma density to remain high in the vicinity of the antenna, thus providing a high density of radicals to etch the underlying material. The RF power supplied to the plasma formed in the vicinity of the antenna, may be set to different levels during each of the two steps, creating plasmas of differing densities. In particular, the power supplied during the etch step is likely to be much greater than during the deposition step.

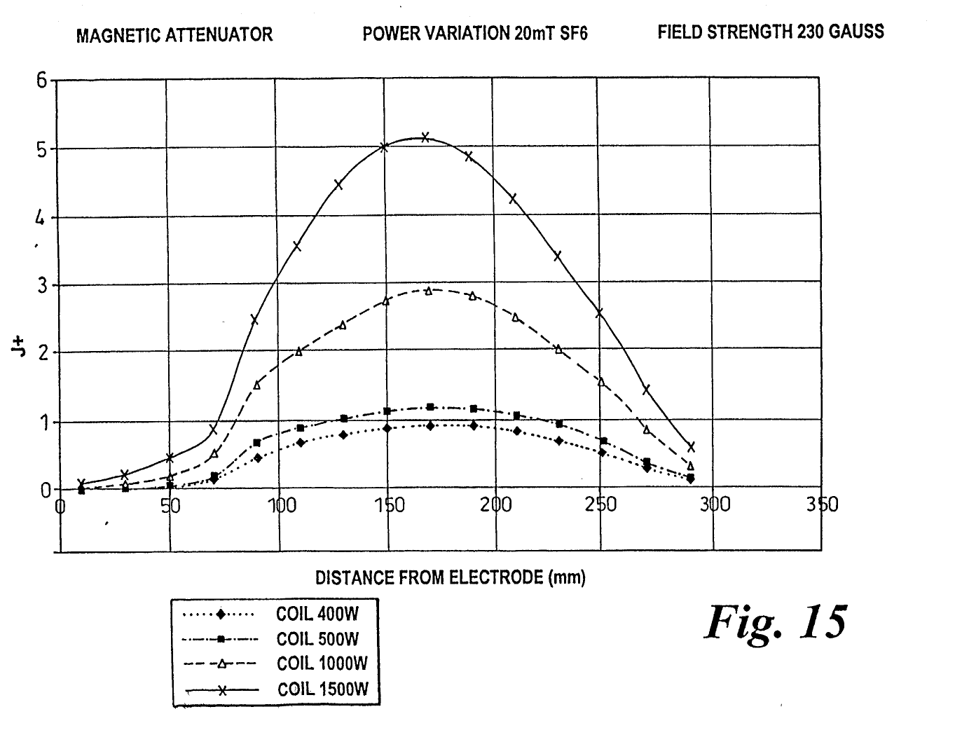

FIG. 15 shows the results of experimental measurements of positive ion current density plotted against distance above the substrate surface at various antenna powers.

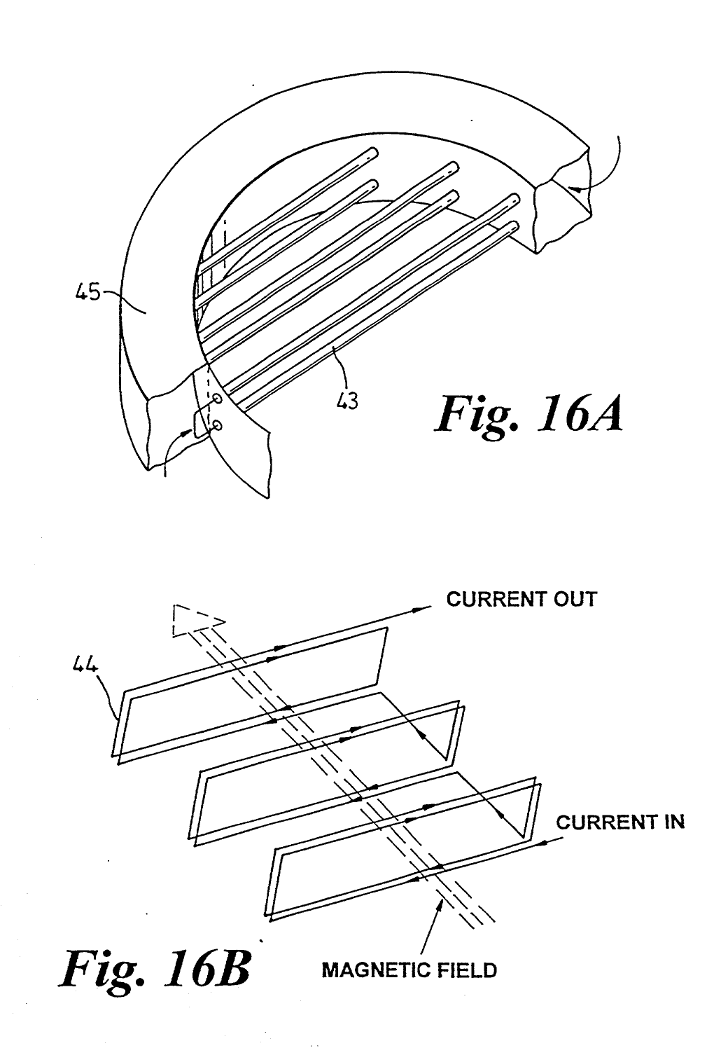

FIGS. 16A and 16B show a cut-away view of a possible arrangement of an electromagnetic attenuator and a possible arrangement of part of a coil winding for the attenuator. The manifold tubes 43 of FIG. 16A carry the windings 44 in the arrangement shown in FIG. 16B. The tubes 43 are linked to a manifold 45 allowing for air or fluid cooling of the windings 44 in the tubes 43.

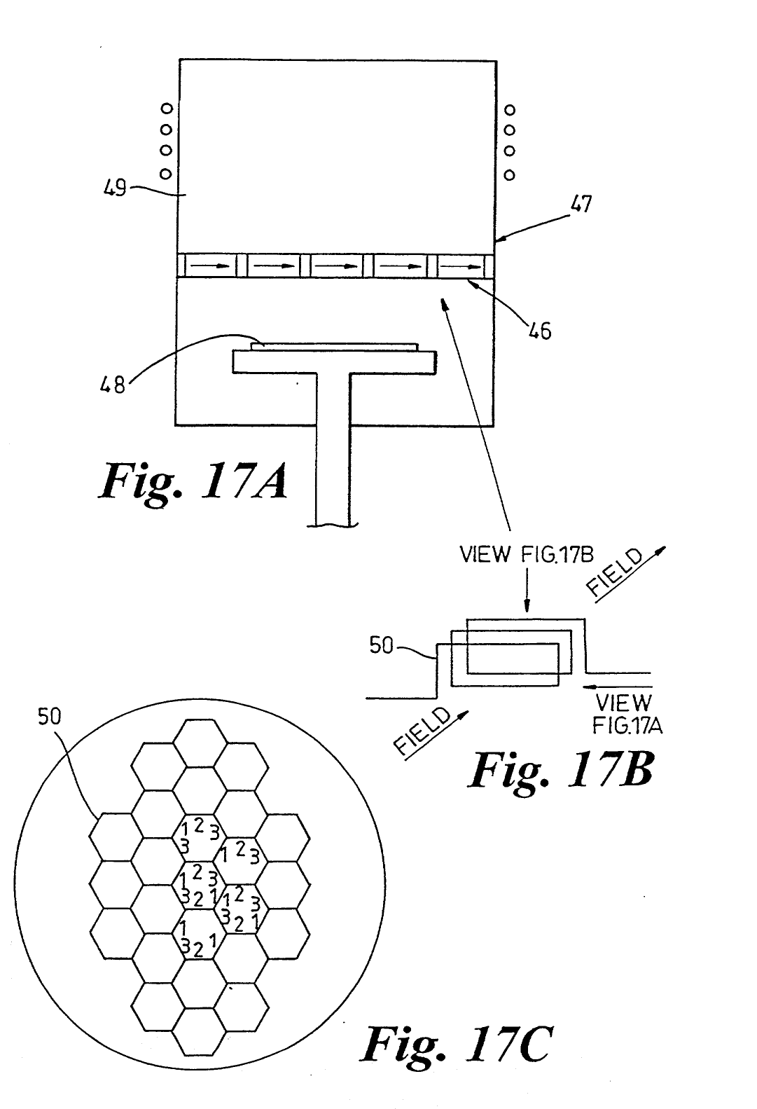

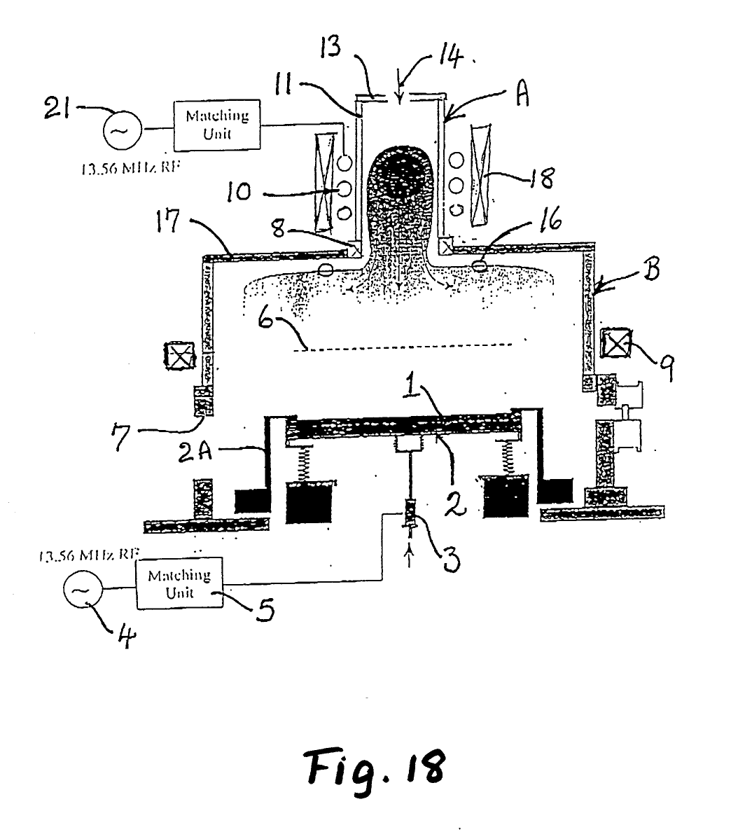

The device shown in FIG. 17A consists of an electromagnetic ion attenuator 46, installed in a plasma-processing chamber 47, with the purpose being to allow neutral radicals to reach the substrate 48 from the high-density plasma region 49, while attenuating the flux of ions that reach the substrate 48.

The device consists of a number of current carrying coils of wire 50 (see FIG. 17B), which each produce a local magnetic field. The coils are located within the plasma processing chamber but are protected from direct contact with the plasma by a structure which has high transparency to the passage of neutrals. The arrangement of the number of coils is such that groups of them are connected together. At a given time one or more groups may be energised, providing a magnetic field across the processing chamber 47, which attenuates the flux of ions reaching the substrate 48, while offering minimal obstruction to the passage of neutrals.

The location of the coils that produce the magnetic field, within the processing chamber, allows a field to be produced that is localised in the vertical direction i.e. does not extend greatly into the high-density plasma region 49, or down towards the substrate 48. This is achieved because the coils can be spaced a few tens of mm apart so that the field is localised to a distance of this order in the vertical direction. This is in contrast to placing coils or permanent magnets outside of the processing chamber, when the magnetic field will extend of the order of hundreds of mm in the vertical direction, because the coils or permanent magnets are spaced hundreds of mm apart. A long range field extending into the high density plasma region may reduce the effectiveness with which power is coupled into the plasma, while a significant field strength at the substrate surface may affect the directionality of ions which reach the substrate.

The groups of coils have their terminations brought out of the processing chamber via suitable feedthroughs that are compatible with the vacuum properties required in the chamber. Fluid or gas may be circulated around the coils to remove the heat produced by ohmic heating of the wire and the heat transferred to the structure surrounding the coils, by the plasma. The structure surrounding the coils must be constructed such as to prevent the fluid or gas from escaping into the processing chamber and further feedthroughs may need to be installed for introducing the fluid or gas. A group of coils is energised by the connection of a power supply through wires to the appropriate feedthrough connections.

A particular arrangment of coils may be such that they are arranged in three groups, with the terminations of the coils such that one wire provides the current feed and a second wire provides the current return for each group. That gives six wires in total for the three groups. A possible array is illustrated in FIG. 17C, which shows a plan view of the coil structure and the location of each of the coil groups, numbered 1, 2, 3 respectively. When a power supply is connected to the pair of wires for the first group of coils, a uniform magnetic field is created across the processing chamber. Connection of the power supply to the second group of coils with the first disconnected, produces a similar magnetic field but now at a 60 degree angle to that produced by the first group of coils, when viewed along the axis of the process chamber. Connection of the power supply to the third group of coils, with the other two groups not energised, leads to a magnetic field that is rotated by a further 60 degrees with respect to the first group of coils. Therefore, if each group of coils is energised in turn, the magnetic field across the processing chamber will rotate in steps of 60 degrees. A reversal of the polarity of the power supply then allows the field direction to rotate in further steps of 60 degrees as each group of coils in turn is energised. The net effect is a full 360-degree rotation of the field direction as the different coil groups are energised, with the power supply polarity reversed at the appropriate stage. The application of a 3 phase AC power supply to the groups of coils, such that each group is connected across one phase, results in the formation of a magnetic field which rotates at the frequency of the supply.

Although in the above description, the coils are orientated to produce a 60 degree rotation of the field direction when each group in turn is energised, this does not preclude the use of coils orientated to produce larger or smaller angular changes to the direction of the magnetic field. It is not essential that coil groups are energised in a particular order. Therefore the net effect may be a clockwise or anticlockwise rotation of the field or any other sequential or random orientation.

It is desirable to rotate or otherwise alter the magnetic field direction during processing to reduce any non-uniformities in the processing of the substrate due to the influence of the magnetic field on the trajectories of those ions which reach the substrate.

In conclusion, the construction and operation of an ion attenuator using a number of groups of coils located inside the processing chamber has three potential benefits.

1. The magnetic field across the chamber is more localised in the vertical direction than if coils or permanent magnets were located outside the chamber.

2. The use of coils rather than permanent magnets allows the field strength to be varied during a process; in particular it allows the field strength to be switched between different levels during different steps of a process.

3. The magnetic field across the chamber can be rotated to improve the uniformity of the process, when the magnetic field may influence the directionality of those ions that reach the substrate.

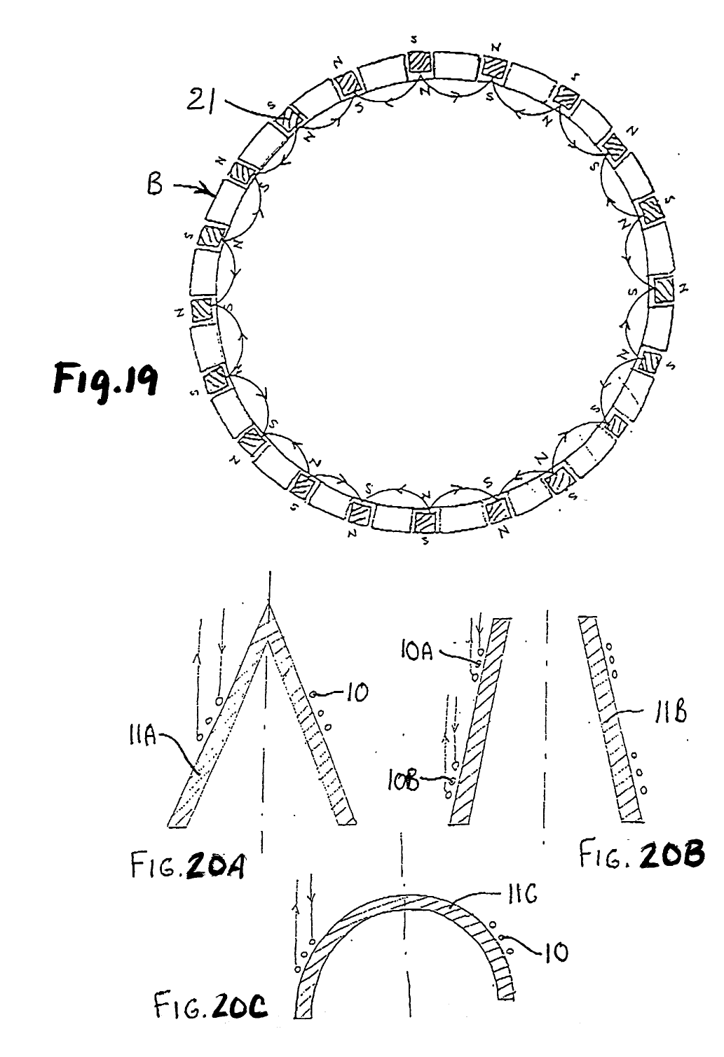

The system of a single first chamber A in which plasma is produced and allowed to flow into the second chamber B, in which the wafer is located, is shown diagrammatically in FIG. 18. The wafer 1 is mounted on a wafer support 2 in the lower chamber B. Good thermal contact is maintained between the wafer and a temperature-controlled section of the support by means of mechanical clamping 2A of the wafer, or by electrostatic clamping, or by other means appropriate to the situation. A thin layer of pressurised gas such as helium, injected through an inlet 3, may be used to fill the small gap between the back of the wafer and the support 2 in order to improve the conduction of heat between the two surfaces. The appropriate parts of the support may be connected to an RF or DC, continuous or pulsed voltage, power supply, for example the RF supply 4, via a suitable impedance matching unit 5, to create a controlled potential difference across the sheath formed above the wafer, thereby controlling the energy of ions impinging on the wafer. The normal processing height within the chamber is indicated at 6. Gas is evacuated through a pumping port 7.

Permanent magnets 21 (as shown in FIG. 19) may be installed around the perimeter of chamber B (and chamber A if appropriate) in columnar form to define a “magnetic bucket”. A “multi-cusp” or “picket fence” arrangement serves to reduce the diffusion of ions and electrons to the walls of the chamber. Historically a “magnetic bucket” configuration has been utilised to increase the plasma density within a chamber because, for a given rate of production of ions and electrons within the volume, the rate of loss to the walls is reduced compared with the situation in which the “magnetic bucket” is not present. If magnetic confinement is provided for chamber A, it is primarily to serve this purpose and allow a high density plasma to be formed with a high density of neutral radicals.

Where there is a requirement to reduce the number of ions reaching the wafer compared with the number of radicals, it would at first sight appear illogical to add magnetic confinement to chamber B, since those ions which diffuse into chamber B will be confined more effectively than if the “magnetic bucket” had not been present. For chamber B, however, the purpose of providing magnetic confinement is primarily to increase the uniformity of the ion flux that reaches the wafer. With no magnetic confinement around chamber B, diffusion of plasma from chamber A down into chamber B, results in ions and electrons being lost to the walls of chamber B, before reaching the wafer position. The plasma density decreases with distance from chamber A to the wafer, and becomes increasingly non-uniform, with the highest density on the axis of the chamber. Magnetic confinement around chamber B reduces the loss of plasma to the walls, and therefore ensures that the uniformity of the plasma at the wafer position is considerably increased. The proposal for magnetic confinement around chamber B is not intended to preclude the use of a system in which there is no magnetic confinement around chamber B. That is the “magnetic bucket” is only utilised when there is an advantage in so doing.

In order to obtain high numbers of neutral radicals at the wafer position, with low numbers of ions, but with good spatial uniformity of the ions, it is necessary to provide good confinement of ions within chamber B, but at the same time significantly reducing the number of ions diffusing out of chamber A compared with the number of radicals. A magnetic plasma attenuator integral with chamber A, or between the two chambers, can be used in conjunction with the plasma confinement in chamber B to achieve the required result. A dipole magnetic plasma attenuator for this purpose may be formed by a permanent magnet or electromagnet.

At the level where the wafer is processed, a solenoidal magnetic field is desirably formed inside the chamber B by an electromagnet 9 located either outside (as shown) or inside of the chamber. The strength of the field may be controlled such that it is of a different value during separate steps of a switched process, and in addition may be ramped in value either up or down for either respective step as the process progresses. The purpose of this field is to assist in the control of the directionality of the ions reaching the wafer surface and in the uniformity of the ion flux across the surface of the wafer.

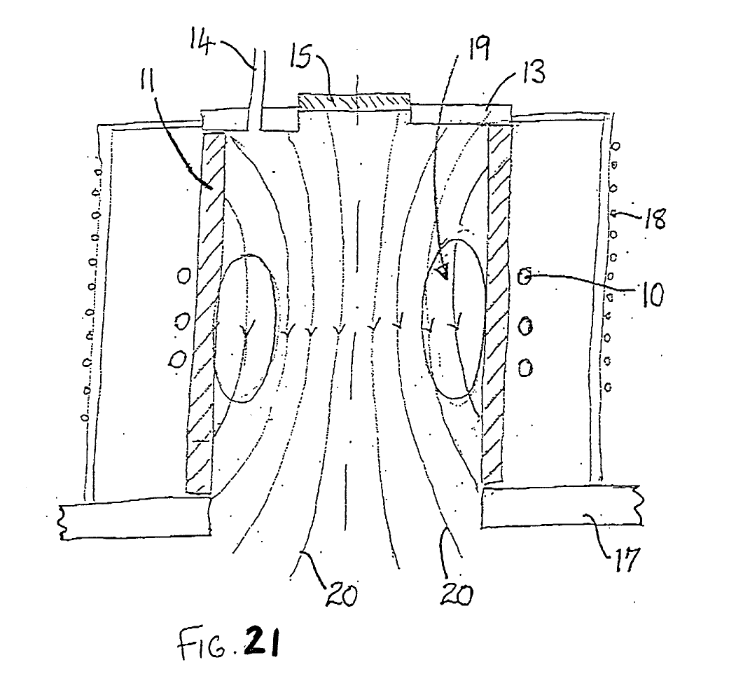

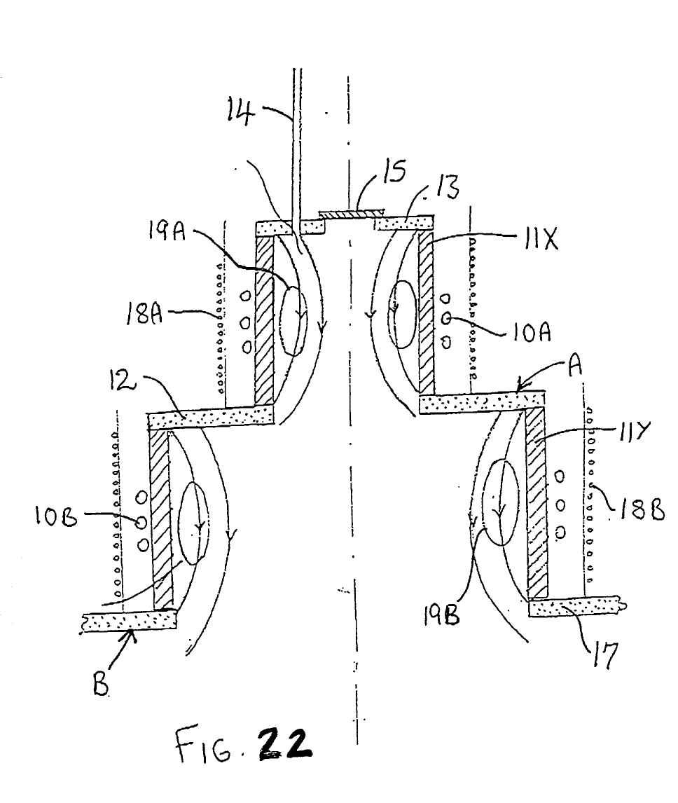

The process plasma is formed in the upper chamber A. For the remainder of this description reference will be to a plasma created and sustained by the inductive coupling of radio frequency power. This does not, however, preclude the use of other means to form the plasma, such as by the use of microwaves, (including in the form of electron cyclotron resonance), helicon waves, or DC means with and without a heated filament as an electron source. In FIG. 18 an antenna 10 is shown located around a cylindrical tube 11 of dielectric material, through which RF power (from a supply point 21) is inductively coupled into the plasma formed inside the tube. The tube geometry can be other than that shown, for example square or hexagonal or other shape in cross-section. The geometry may alternatively take the form of a cone 11A, truncated cone 11B or hemisphere 11C or combination of these geometries (FIG. 20). In most circumstances, one antenna 10 will be used to couple power into the plasma. However, the uniformity of the etch or deposition process may be improved by the use two or more antennae 10A, 10B, particularly if they are located around different diameter sections of the dielectric tube 11 (FIG. 20B).

The dielectric material from which the tube 11 is formed may be alumina or quartz or other suitable material compatible with the process gases. It may be advantageous to use a material such as silicon carbide, which has higher thermal conductivity than alumina, and therefore enables better transference of heat from the internal walls, adjacent to the plasma, to external cooling means. Because of its higher electrical conductivity, silicon carbide may assist in reducing the capacitive coupling of RF power into the chamber when inductive coupling is the desired mode. Aluminium nitride is an alternative material, combining high thermal conductivity with low electrical conductivity, and allowing good heat transference but with little effect on the coupling of RF power from an external antenna 10 into the plasma. When the plasma density is high, the high thermal conductivity of either aluminium nitride or silicon carbide can be a particular advantage. This is because the temperature gradient between the inside and outside of the tube is reduced compared with a material with less good thermal conductivity such as alumina, and therefore differential expansion of the tube is reduced. Significant differential expansion of the dielectric tube can lead to crack formation and propagation, with loss of vacuum integrity.

In some circumstances there may be advantages in terms of the uniformity of processing of the wafer, to use a geometry (see FIG. 22) in which chamber A is formed of two, or more, differing-diameter cylindrical dielectric sections 11X, 1Y. RF power is then coupled into the plasma by two, or more, separate antennae 10A, 10B each located around the respective cylindrical sections. This may be constructed out of one piece of dielectric material, or may consist of two, or more, separate sections 11X, 11Y with a conducting or non-conducting interface flange 12 with appropriate vacuum sealing means. Although cylindrical sections are described, this is not to preclude other geometrical shapes such as those with square or hexagonal cross-sections. The two, or more, separate antennae would utilise separate impedance matching units and either separate RF power supplies or a split output from a single supply. With reference to FIG. 22, the power coupled into the plasma via antenna 10A has more effect on the ion and radical fluxes reaching the centre of the wafer, while the power coupled into the plasma via antenna 10B has more effect on the ion and radical fluxes reaching the outer region of the wafer. Lateral diffusion of ions and radicals means that the above effect is not clear cut, but is essentially true if the distance between the upper chamber A, and the wafer is not too great. Adjustment of the relative levels of RF power fed to the two, or more, antennae would allow adjustment of the plasma profile within this chamber, and of the effect of the plasma at the wafer. Relative power levels could be adjusted to different values depending on whether an etch step or a deposition step was in progress.

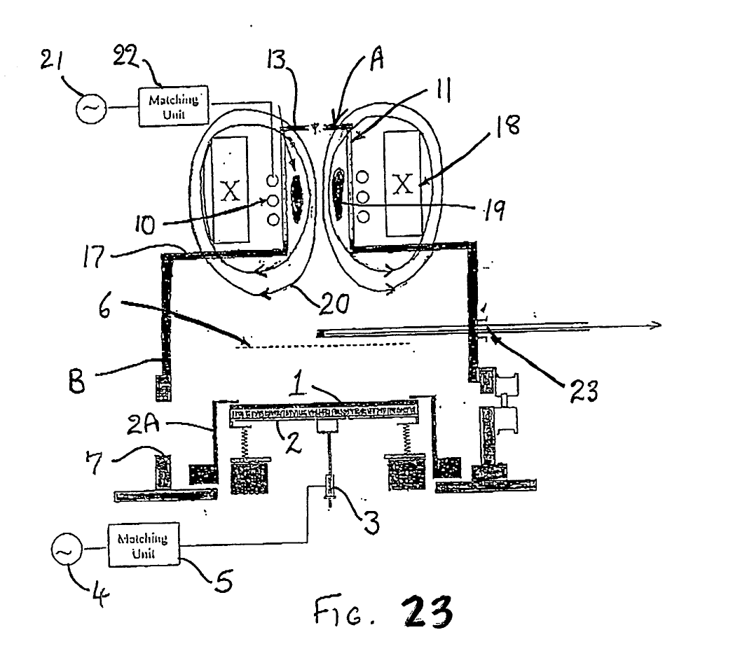

With reference to FIG. 18, the upper chamber A is formed out of the dielectric cylinder 11 defining the side walls, with the top closed by plate 13 with suitable vacuum sealing means to the cylinder. The top plate will normally be constructed out of metal, with a suitable connection 14 to allow process gas to be fed into the chamber. Suitable means may be incorporated to distribute the gas uniformly in the chamber. A window (for example as at 15 in FIG. 21 or FIG. 22) may be incorporated in the top plate to allow observation of the plasma and/or wafer for process end-point measurements etc. The lower end of the dielectric cylinder interfaces with the lid 17 of the lower chamber B, either directly or with an intermediate short pipe section, usually formed of metal, which may be grounded or allowed to float electrically or biased to a chosen potential.

Although the above description includes the feeding of process gas through the lid of the upper chamber A, it may under certain circumstances be desirable, additionally or alternatively, to feed gas back up into this chamber from a gas ring 16 mounted within the lower chamber B, near the lid 17 of the lower chamber. In some circumstances one gas may be fed through the lid of the upper chamber A and a different gas may be fed from the gas ring mounted within the lower chamber B. Where the geometry of the upper chamber is a hemisphere or cone, manufactured entirely out of dielectric material, then it will not be possible to feed gas into the top of the upper chamber A and a gas ring 16 within the lower chamber is then essential.

When a switched process is used, there may be advantages to feeding the appropriate process gas through either the inlet in the lid of the upper plasma chamber A, or through the gas inlet ring in the lower process chamber B, depending on whether the etch step or the passivation step is being executed. Alternatively it may be desirable to feed gas via both routes for one step and only one route for the other step. Whichever route is used to feed the process gas into the apparatus during each of the two steps, appropriate control of the inlet gas flows may be by means of mass flow controllers. An automatic pressure control valve (APC) may be used to control the gas conductance from the process chamber to the vacuum pumps, and this will allow the process chamber pressure to be controlled.

In some circumstances it may be desirable to utilise significantly different pressures in the process chamber for each of the two steps in a switched process. For example, high pressure during the etch step and low pressure during the passivation step. This can be achieved by suitable fast acting control of the mass flow controller(s) feeding gas into the chamber and the pressure control valve controlling the gas conductance between the chamber and the vacuum pumps.

For a plasma to be formed in the upper chamber A, RF power must be applied to the antenna 10 surrounding the upper chamber with the required process gas introduced via the relevant inlet means. Neutral radicals are formed by energetic electrons from the plasma impacting on the neutral gas and, therefore, within the upper chamber A, ions, electrons, radicals and un-dissociated feed gas will exist. All of these species will diffuse into the lower chamber B, with some losses in numbers due to re-combination in the volume and at the walls. Ions and electrons will re-combine readily at the walls of the chamber; however radicals may survive a number of collisions. When magnetic confinement is present in the lower chamber B, the loss of ions and electrons to the walls of this chamber can be significantly reduced.

Restriction of the size of the aperture in the lid 17 of the lower chamber B, where the upper chamber A is mounted, or the internal diameter of the intermediate short pipe section when present, will allow a higher pressure differential to be maintained between the upper chamber and the lower. This may increase the process efficiency because the higher pressure in the upper chamber can benefit the formation of ions and radicals because of increased collisions, while a reduced pressure in the lower chamber reduces the incidence of re-combination within the volume. This arrangement can clearly only be utilised when there is a gas feed into the upper chamber, and may have detrimental results if losses of ions or radicals at the restriction are increased. A variable aperture automatic pressure control (APC) arrangement may be incorporated at this position. However the physical design of the APC may reduce the uniformity of the ion flux, in particular, reaching the wafer.

If desired, a dipole magnetic field, either formed by the use of permanent magnets 8 or an electromagnet, may be applied across the lower end of the upper chamber A (or across the intermediate short pipe section when present), to form a magnetic plasma attenuator. The permanent magnets or electromagnets used to create the field will generally be located outside of the chamber, but may be partially or wholly internal to the chamber. The action of this field is to deflect electrons, and thence ions, to the wall where they are lost, and therefore to allow control of the numbers of ions passing into the lower chamber, whilst not reducing the radical flux.

If the magnet structure is inside the chamber, then by its geometry it will be expected to increase slightly the local loss area for radicals. Control of the relative numbers of ions compared with radicals, passing into the lower chamber, allows greater control of the overall process. In particular for a switched process, if an electromagnet or hybrid of a permanent and an electromagnet is utilised, then it is feasible to control the relative numbers of ions to radicals to different appropriate ratios for each of the two steps.

Control of the RF power into the plasma in the upper chamber A determines the numbers of ions and radicals formed, and in general both will increase with increasing power input. Process gas flow and pressure will also have an effect. There is increasingly a need to produce higher etch rates, which for chemical reactions requires large numbers of radicals while the numbers of ions may need to be restricted to reduce unwanted damage to the etched structure or the mask. The combination of control of the plasma density to produce large numbers of ions and radicals, in conjunction with a “magnetic plasma attenuator” to reduce the ion component reaching the wafer, permits high, predominantly chemical, etch rates to be achieved with reduced ion-associated detrimental effects. Detrimental effects associated with high ion fluxes to the wafer include high mask etch rates and problems in sidewall profile control of etched features.

The dipole form of “magnetic plasma attenuator” has a drawback in that the application of a magnetic field across the upper chamber leads to a perpendicular deflection of ions and electrons such as to reduce the cylindrical symmetry of the ion flow from the region in which the plasma is formed, down towards the wafer. This may reduce the uniformity of the process carried out on the wafer.

A solenoidal magnetic field generated by a coil 18 around the upper chamber A, as shown in FIG. 21, has advantages as a “magnetic plasma attenuator”, over the dipole field described above. Cylindrical symmetry is maintained while, by judicious adjustment of the magnetic field strength, a dense plasma region 19 formed inside the tube 11 and adjacent to the antenna 10 is at least partially trapped by the field lines 20. These field lines intersect the wall of the upper chamber A near or on the lid 13, and either on the upper chamber wall near its base, or on the lid 17 or upper walls of the lower chamber B. The omission of a magnet 8 (creating a dipole field) removes a possible source of non-uniformity of the plasma. Significant numbers of radicals can be created in the upper chamber A, which then diffuse into the lower chamber. The associated ion flux is reduced, however, because of losses where the field lines intersect the walls, thereby ensuring that the ratio of ion numbers to radical numbers reaching the wafer is reduced in line with requirements. As shown in FIG. 22 there may be separate solenoids 18A, 18B provided for each of the sections 11X and 11Y, which allow for greater control of the plasma. As can be seen separate dense plasma regions 19A and 19B are created by the two antennae.

When magnetic confinement is provided in the lower chamber B, some electrons trapped on magnetic field lines from the solenoid 18 around the upper chamber A, may encounter the strong magnetic fields at the walls of chamber B. This may lead to some local mirroring of the electrons so that they may survive to take part in further excitation and ionisation collisions with gas molecules. The situation may occur therefore where the strength of the field from the solenoid around the upper chamber A is sufficient to reduce significantly the flux of ions to the wafer 1, whilst at the same time excitation and ionisation collisions are increased. An increased rate for radical formation by this mechanism has the potential to increase the rate of chemical etching of the wafer.

Experimental operation has been carried out, of a de-coupled plasma source and process chamber incorporating some of the features described already. The arrangement was as shown in FIG. 23. The chamber A, in which the plasma was generated, consisted of a dielectric tube 11 with an RB antenna 10 located around its centre section and held in this position by suitable support means. RF power from the RF power supply 21 was fed to the antenna via a matching unit 22, which matched the plasma impedance to the 50 ohm impedance of the power supply. An electromagnetic solenoid 18 was positioned around the plasma chamber A so that, when energised, a magnetic field pattern was produced as indicated by the representational magnetic field lines 20. This electromagnetic solenoid 18 was the only form of magnetic ion attenuation incorporated on the de-coupled plasma source and process chamber arrangement. No form of dipole magnetic ion attenuator was incorporated between the plasma source and process chambers.

The process chamber B, incorporated a “magnetic bucket” (as in FIG. 19) formed from small permanent magnets located around the perimeter, in order to improve the plasma confinement, but no electromagnet was operated around the process chamber, at or near the wafer processing height 6.

A particular experiment was carried out to determine the effectiveness of the solenoidal magnetic field, created by the electromagnet 18 around the chamber A, in which the plasma was formed, in attenuating the flux of ions reaching a wafer 1 mounted in the process chamber B. In this experimental work a silicon wafer was utilised as the workpiece, but it is to be understood that the workpiece could equally be a wafer of another material or an alternative object to be subjected to a plasma induced process.

A small Langmuir probe 23 was inserted through a port in the wall of process chamber B so that it could be moved along a diameter of the chamber just above the surface of a test wafer which had been loaded into the chamber. The Langmuir probe was used to measure the ion flux immediately above the wafer as a function of position across the diameter of the chamber.

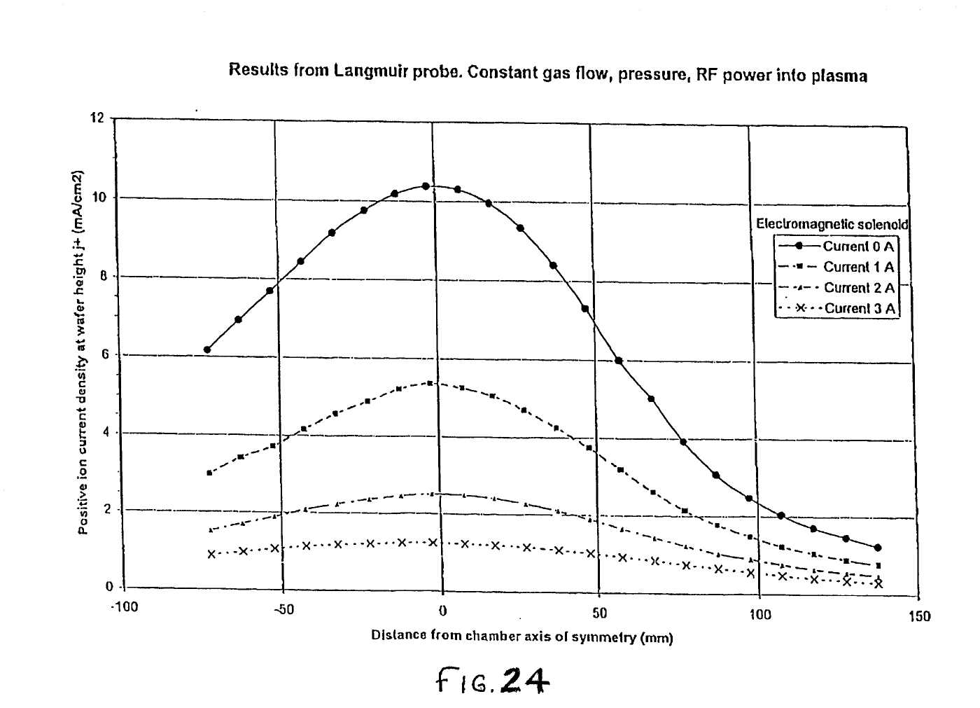

Experimental results of ion flux as a function of position across the diameter of the process chamber are shown in FIG. 24. Each of the curves is for a different value of the current passed through the electromagnetic solenoid around chamber A in which the plasma was formed. The strength of the magnetic field increases as the current passed through the solenoid is increased. From the graph, it can be clearly seen that as the magnetic field strength is increased, the ion flux reaching the wafer processing height, is reduced and to some extent the magnitude of the ion flux becomes more uniform over a significant part of the chamber diameter.

The experimental measurements of ion flux carried out by means of the Langmuir probe have been reinforced by further experiments in which the use of the electromagnetic solenoid around the chamber A has reduced ion-associated effects on wafers being processed, while allowing high chemical etch rates to be obtained.

The use of an electromagnetic ion attenuator is an effective way of reducing the ion flux reaching a wafer while allowing a high neutral radical flux to reach the wafer. This is clearly a useful facility when an etch process is primarily chemical, and so driven by the radical flux, but the mask is primarily eroded by the flux of ions reaching it.

In some circumstances it may be desirable to reduce the proportion of ions reaching the wafer surface when compared to the numbers of neutral radicals, to levels which are lower than that which can be achieved by magnetic attenuation alone. Alternatively, there may be reasons for not wishing to operate the magnetic attenuator at high field strengths. A method of achieving the required result for certain processes is to pulse on and off the plasma formed in chamber A, at the same type as operating the magnetic attenuation means.

In the specific case of the etching of silicon by the gas SF₆ it is understood that the etching of the silicon is primarily due to a chemical reaction of the fluorine radicals formed in the plasma. It is also known that for certain operating conditions, the fluorine radicals that are formed by the plasma can exist for a significant length of time after the plasma has been extinguished. The ion density, however, usually decreases very quickly after the plasma is switched off. This difference in lifetimes of the two species can be used to advantage if the plasma is pulsed on and off at a suitable rate and with an appropriate pulse mark space ratio. Boswell and Porteous [J. Appl. Phys. 62(8), American Insti. Of Phys. 1987] describe the pulsing of an SF₆ plasma in which, for 2 millisecond pulses with a 10 millisecond period, the mean silicon etch rate is essentially the same as the rate for a continuous plasma. The lifetime of the charged species was found to be less than 1 millisecond, which is typical of this kind of low pressure discharge. For the pulsed plasma alone, the results of Boswell and Porteous indicate that he ratio of time-averaged ion flux to radical flux may be reduced to less than 0.3 times the ratio in a continuous plasma. It can therefore be anticipated that the combination of a pulsed plasma with the magnetic attenuator concept has the potential to reduce the ratio of ion flux to radical flux reaching the wafer to a value which is smaller than either technique in isolation.

The de-coupled plasma source and wafer processing chamber shown in FIG. 18 or FIG. 23 can be used to great effect for carrying out certain processes on certain sized wafers. In general, the neutral radicals formed in the plasma source diffuse down to the wafer where they react chemically with the surface. The ion flux reaching the wafer surface can be controlled by the use of the magnetic attenuation means and if necessary by the pulsing of the plasma in the source. While the use of an electromagnetic solenoid ion attenuator 18 around the plasma source acts to reduce the flux of ions reaching the wafer, and to some extent assists in making the ion flux more uniform across the wafer, the simple de-coupled source may have some limitations due to its geometry.

In order to form an efficient high-density plasma in the source for acceptable levels of applied RF power, its volume should be reasonably small. The electromagnetic solenoid around the source can then also be reasonably small, with low current requirements. The neutral radicals formed in the source diffuse down to the wafer and the flux reaching the wafer as a function of radius, is determined in part by the geometry of the plasma chamber, but also by vacuum pumping arrangements for the process chamber and any baffle systems.

The ion flux magnitude and uniformity at the wafer surface is determined by the magnetic attenuator, but also by the geometry of the source chamber and whether magnets are located on the perimeter of the process chamber B to enhance the plasma confinement. For a small diameter plasma source compared with the diameter of the wafer, it may be difficult to maintain a near uniform ion flux to the wafer from the centre of the wafer out to the edge. For a single de-coupled source on the same axis as the wafer, the ion flux density to the wafer is likely to decrease from the centre to edge.

In many cases a small gradient in the ion flux density between the centre of the wafer and the edge will not cause any appreciable problem, particularly if the process is predominantly chemically driven. In those circumstances, where the process is ion driven or depends on a well defined ion flux impinging on the wafer perpendicular to the wafer surface for at least part of the process, the uniformity and directionality of the ion flux may not be sufficient with the processing apparatus geometry described above. If this is the case, further measures may need to be taken to improve the uniformity of the ion flux reaching the wafer.

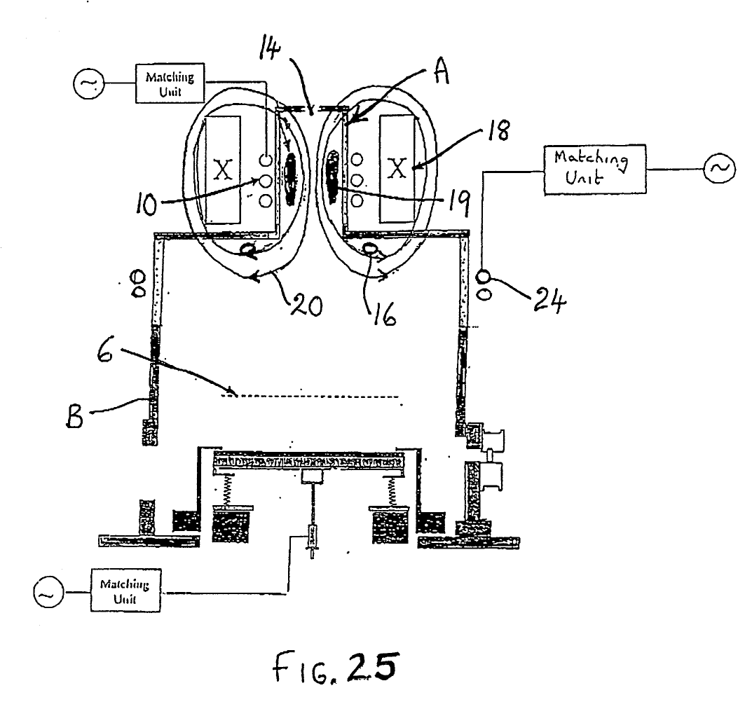

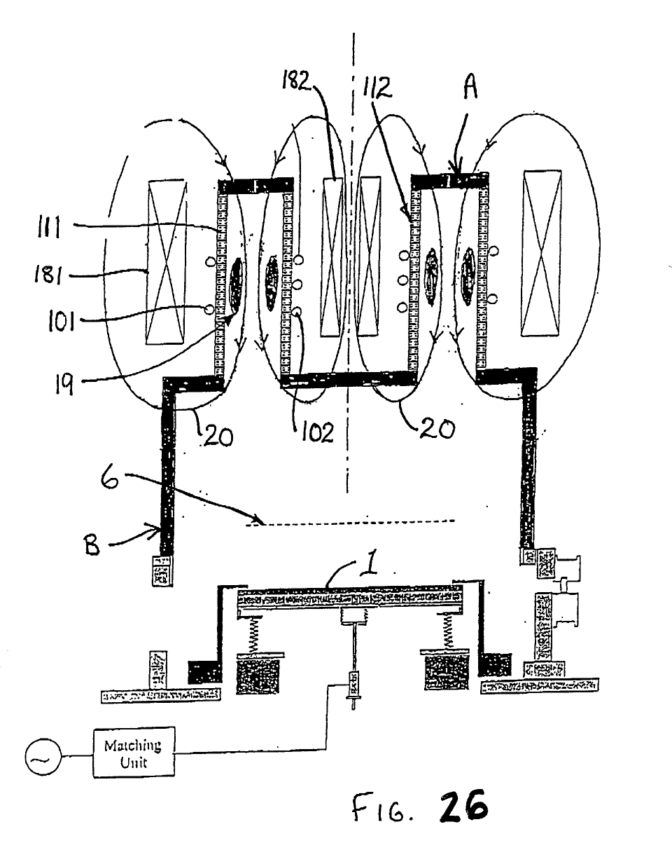

A particular configuration of the plasma processing equipment designed to help to reduce the problem described above is shown in FIG. 25. This arrangement is based around the use of a de-coupled source of similar form to that described in earlier parts of this document. Plasma is formed in the smaller source chamber A with neutral radicals diffusing down into the process chamber B in which the wafer is supported. Ions from the plasma also diffuse into the process chamber, but a magnetic ion attenuator 18 is operated to reduce the ion flux as required. Magnetic plasma confinement may be utilised on parts of the walls of the process chamber B in order to improve the uniformity of the ion flux to the wafer.

Where the alternative configuration of the de-coupled processing apparatus differs from that described previously is that a secondary plasma is formed within the process chamber by the use of the RF power coupled in by an antenna 24 around the upper section of the process chamber B. This description of the inductive coupling of RF power into a secondary plasma is given by example and is not intended to preclude the generation of a secondary plasma within the process chamber by other means, for example by capacitive coupling of RF power, or by the use of microwave power.

An antenna around the upper section of the process chamber B forms an annular plasma within the chamber, which then diffuses throughout the chamber volume. In general the power supplied to this antenna will be considerably less than that supplied to the antenna 10 around the smaller source chamber A. The prime purpose for the formation of this secondary plasma is to provide additional ions near the edge of the plasma chamber, thereby increasing the flux of ions towards the edge of the wafer. By careful adjustment of the power fed to this secondary plasma the additional ions can make up for the shortfall in the ion flux towards the edge of the wafer arriving from the source chamber A, after passage through the magnetic ion attenuator 18. While in most cases the secondary plasma is used to increase the ion flux towards the edge of the wafer, and the extra radicals produced are of lesser importance, there may be occasions when these extra radicals are of benefit to the process being performed. If required, it would be feasible to place a solenoidal magnetic ion attenuator around the section of the process chamber B where the antenna 24 is located, and then control the relative numbers of ions and neutral radicals emerging into the main volume of the process chamber.

For the alternative configuration of the de-coupled source plasma processing apparatus described above, the process gas will generally be fed in through the inlet 14 in the lid of the plasma chamber A. However, it alternatively may be fed in through a gas ring 16 located inside the process chamber B, near its lid. In some circumstances the process gas may be fed via both inlets 14 and 16 simultaneously, or different gases may be fed via either route.

When a switched process is being carried out, the gas may be fed to either one or both of inlets 14 and 16 depending on which step is taking place. For example, when the etch step is carried out, gas may be fed primarily into the top of the plasma chamber A through inlet 14, where it is subjected to the dense plasma to produce copious numbers of etch radicals. When the passivation step is carried out, gas may be primarily fed in via the gas ring 16, and the antenna 24 around the upper section of process chamber B is then used to form the plasma, with no plasma or a weak plasma formed in chamber A. This example describes one possible scenario, and is not intended to limit in any way the options for the gas feed route or region in which the plasma is generated for either step of a switched process.

As described previously for the basic de-coupled source apparatus, the pressure in the process chamber B may be controlled to be significantly different during each of the two steps of a switched process.

While the above description has been for an antenna 24 outside and around the upper portion of the process chamber B to couple power into a secondary plasma, this does not preclude the use of a suitably insulated and supported antenna located within the process chamber. To serve the same purpose as the externally mounted antenna, this internally mounted antenna would generally be located on a large diameter in the vicinity of the perimeter of the process chamber. The internally mounted antenna would require suitable feed through connections in one of the walls of the process chamber to allow the connection of RF power and possibly for the circulation of a cooling medium through a hollow antenna.

A further version of a de-coupled source plasma processing apparatus incorporating magnetic ion attenuation means is shown in FIG. 26. In this arrangement the process chamber is essentially as shown in FIG. 18 or FIG. 23, but the plasma source chamber differs. In this case, the plasma source is of annular form, utilising one antenna 101 positioned radially outside of the outer dielectric cylinder 111 and a second antenna 102 positioned radially inside of the inner dielectric cylinder 112. These two antennae may be supplied by RF power from two separate power supplies or by one power supply using a suitable power splitting device. In some circumstances there may be advantages in adjusting the relative power fed to each antenna for fine adjustment of the plasma characteristics, but it is considered that in most circumstances the two antennae would be driven together with a fixed power ratio.

Two electromagnetic solenoids are incorporated into the structure, one 181 is located radially outside of the outer antenna 101 and the other 182 is located radially inside of the inner antenna 102. By suitable adjustment of the flow of current in each of these solenoids, an electromagnetic ion attenuator can be formed for the annular plasma source. It should be noted that in order to form the magnetic field line pattern 20 shown in FIG. 26 (which is effective in attenuating the ion flux reaching the wafer), the current flows in the two solenoids 181 and 182 must be such as to produce opposing field directions within each solenoid. In order to achieve the required field strengths from each of the two solenoidal electromagnets, each may be driven from a separate current source. However, in many circumstances it may be preferable to use a single current source with current division between the solenoids in a predetermined ratio to achieve the required ratio of magnetic field strengths.

There is a potential advantage of using the annular plasma source for the de-coupled source plasma processing apparatus when large wafers are to be processed, rather than the simpler small cylindrical plasma chamber. This is because the geometry ensures that radicals and ions enter the process chamber from the plasma chamber at larger diameters and by judicious choice of wafer processing height, the different diffusion characteristics can be used to advantage. This may be particularly important for achieving a uniform flux of ions to the surface of the wafer.

The above structure has been described in terms of a cylindrical annular form; however, this is not intended to preclude similar structures having square, hexagonal or other multisided annular forms.

To someone skilled in the art, it would not be unreasonable to consider repeating this annular plasma source structure of FIG. 26 at two or more different diameters and in one or more planes, if there was a need to feed ions and radicals into a large process chamber. The combination of an annular plasma source of suitable diameter with a simple cylindrical plasma source on the axis of symmetry may have application in certain circumstances.

While it is considered unlikely that it will be necessary to provide an additional antenna around the upper section of the process chamber B when an annular plasma chamber is used, this option may still be considered if desirable. When operating the equipment to carry out a process within apparatus of the invention, it is possible for the field strength of any one or more electromagnets employed to create an attenuation magnetic field to be varied as a function of time, thus altering the time variability of the ion attenuation.

While the invention has been described in detail in terms of specific embodiments, those skilled in the art will recognize that the invention can be practiced with various modifications or changes within the spirit and scope of the appended claims.

What is claimed is:

1. A plasma processing apparatus comprising a first chamber provided with a plasma inducing device designed to produce a plasma in said first chamber, and a second chamber into which plasma so produced can diffuse to act upon a workpiece being processed, and a magnetic field production device positioned relative to at least the first of said two chambers and constructed to cause attenuation of the ions which diffuse into the second chamber and approach the workpiece, by directing a proportion of the ions to a loss surface of either chamber.

2. Apparatus according to claim 1, wherein the magnetic field production device comprises permanent magnets or electromagnets installed around the side wall of the first chamber.

3. Apparatus according to claim 1, wherein the magnetic field production device around the first chamber is a solenoid whose output can be varied.

4. Apparatus according to claim 1 and incorporating an additional plasma inducing device at the upper region of the second chamber.

5. Apparatus according to claim 4, wherein permanent magnets, electromagnets or a solenoid are installed also around said additional plasma inducing device at the upper region of the second chamber, as a further magnetic field production device.

6. Apparatus according to claim 1, wherein the magnetic field production device comprises a magnetic structure formed at the junction of the two chambers to create a dipole magnetic field there.

7. Apparatus according to claim 1, and incorporating a ring gas feed within the second chamber, below the junction point of the two chambers, in addition to a gas feed inlet to the top of the first chamber.

8. Apparatus according to claim 1, wherein a solenoid device whose output can be varied is provided for the second chamber at a position to create a magnetic field inside the second chamber at the level of the workpiece to steer ions towards the workpiece.

9. Apparatus according to claim 1, wherein the second chamber is provided with a magnetic bucket arrangement created by an array of magnets around the chamber wall.

10. Apparatus according to claim 1, wherein the first chamber geometry is formed as a cylinder, a stepped cylinder, a cone, a truncated cone, or a hemisphere, or a combination of these geometries.

11. Apparatus according to claim 1, wherein the first chamber is of annular form and the annular magnetic field production device comprises separate permanent magnets, electromagnets or solenoids located both within and around said annulus.

12. Apparatus according to claim 11, wherein further annular forms of a first chamber with pairs of attenuation magnetic field production devices and with plasma inducing devices are positioned concentrically of one another.

13. Apparatus according to claim 1, wherein the first chamber is formed of two or more differing-diameter cylindrical dielectric sections, one above the other, each such section being provided with its own plasma inducing device.

14. A plasma processing apparatus comprising a first chamber provided with a plasma inducing device designed to produce a plasma in said first chamber, and a second chamber into which plasma so produced can diffuse to act upon a workpiece being processed, wherein the first chamber is formed of two or more differing-diameter cylindrical dielectric sections, one above the other, each such section being provided with its own plasma inducing device.

15. Apparatus according to claim 13, wherein the portions joining the individual sections of said first chamber are formed of metallic or dielectric material.

16. Apparatus according to claim 13, wherein the portions joining the individual sections of said first chamber are positioned perpendicular to or angled to said sections.

17. Apparatus according to claim 13, wherein the multi-section first chamber has a magnetic field production device associated with more than one of said sections, each constructed to cause attenuation of the flux of the ions which diffuse into the second chamber and approach the workpiece.

18. Apparatus according to claim 14, wherein the portions joining the individual sections of said first chamber are formed of metallic or dielectric material.

19. Apparatus according to claim 14, wherein the portions joining the individual sections of said first chamber are positioned perpendicular to or angled to said sections.

20. Apparatus according to claim 14, wherein the multi-section first chamber has a magnetic field production device associated with more than one of said sections, each constructed to cause attenuation of the flux of the ions which diffuse into the second chamber and approach the workpiece.

21. Apparatus according to claim 1, wherein said first chamber incorporates a dielectric plasma tube formed from aluminium nitride or silicon carbide or other dielectric material having a thermal conductivity sufficiently greater than aluminium oxide to allow high power operation without failure-inducing high thermal gradients arising in the dielectric material.

22. Apparatus according to claim 1, wherein a plurality of said first chambers are provided across the top of the second chamber.

23. A plasma processing apparatus comprising a first chamber provided with a plasma inducing device designed to produce a plasma in said first chamber, and a second chamber into which plasma so produced can diffuse to act upon a workpiece being processed, wherein said first chamber incorporates a dielectric plasma tube formed from aluminium nitride or silicon carbide or other dielectric material having a thermal conductivity sufficiently greater than aluminium oxide to allow high power operation without failure-inducing high thermal gradients arising in the dielectric material.

24. A method of controlling the transmission of a plasma to a workpiece, wherein plasma is created in a first chamber provided by a plasma inducing device, and is allowed to diffuse into a second chamber to act upon a workpiece being processed, and an attenuation magnetic field production device positioned relative to at least the first of said two chambers is operated in a manner to cause attenuation of the ions which diffuse into the second chamber and approach the workpiece, by directing a proportion of the ions to a loss surface of either chamber.

25. A method according to claim 24, wherein said attenuation magnetic field is produced by permanent magnets, electromagnets, or a solenoid whose output can be varied, positioned around the side wall of the first chamber.

26. A method according to claim 24, wherein plasma is also created at the upper region of the second chamber by an additional plasma inducing device.

27. A method according to claim 26, wherein an attenuation magnetic field is additionally produced by permanent magnets, electromagnets, or a solenoid located around said additional plasma inducing device at the upper region of the second chamber, as a further magnetic field production device, to cause attenuation of the ions which diffuse further into the second chamber.

28. A method according to claim 24, wherein said attenuation magnetic field is produced by a magnetic structure formed at the junction of the two chambers to create a dipole magnetic field there.

29. A method according to claim 24, wherein gas is fed into a ring gas feed within the second chamber, below the junction point of the two chambers, in addition to gas fed through a gas feed inlet to the top of the first chamber.

30. A method according to claim 29, wherein different gases are fed into said gas feed inlet and said ring gas feed.

31. A method according to claim 29, wherein the inlet gas flows to the gas feed inlet and the ring gas feed are controlled by separate mass flow controllers.

31. A method according to claim 29, wherein the process chamber pressure is set to different levels for each of different processing steps.

33. A method according to claim 24, wherein the first chamber is constructed from two or more differing-diameter cylindrical dielectric sections and RF power is coupled into the plasma created in the first chamber by two or more separate antennae, each located around the respective cylindrical sections.

34. A method according to claim 33, wherein the relative power levels to the two or more antennae are adjusted to different values depending upon whether an etch step or a deposition step in a switched process is in progress.

35. A method according to claim 24, wherein the plasma inducing device is operated so as to pulse the plasma on and off during operation of the process.

36. A method according to claim 24, wherein magnetic confinement is provided in the second chamber by means of a magnetic bucket arrangement created by an array of magnets around the chamber wall.

37. A method according to claim 24, wherein the field strength of any one or more electromagnets employed to create an attenuation magnetic field is varied as a function of time.
